(19) United States
(12) Patent Application Publication
(10) Pub. No.: US 2016/0197281 A1
(43) Pub. Date: Jul. 7, 2016

(54) PHOTOELECTRIC CONVERSION DEVICE AND FABRICATION METHOD THEREFOR

(71) Applicant: FUJITSU LIMITED, Kawasaki-shi (JP)

(72) Inventors: Satoru MOMOSE, Atsugi (JP); Kota YOSHIKAWA, Atsugi (JP); Shuuichi DOI, Isehara (JP)

(73) Assignee: FUJITSU LIMITED, Kawasaki-shi (JP)

(21) Appl. No.: 15/070,650

(22) Filed: Mar. 15, 2016

Related U.S. Application Data
(63) Continuation of application No. PCT/JP2013/076368, filed on Sep. 27, 2013.

(51) Int. Cl. H01L 51/00; H01L 51/44

(52) U.S. Cl. CPC H01L 51/0036; H01L 51/441; H01L 51/0047; H01L 51/4253

(57) ABSTRACT

In order to form a photoelectric conversion layer of a photoelectric conversion element, mixed liquid including poly-[N-9′-heptadecanyl-2,7-carbazole-alt-5,5-(4′,7′-di-2-thienyl2′,1′,3′-benzothiadiazle)] as a p-type organic semiconductor material and a fullerene derivative as an n-type organic semiconductor material, which configure a bulk heterojunction are applied and dried. The dried substance is exposed in an atmosphere including vapor of a solvent that dissolves the p-type organic semiconductor material preferentially to the n-type organic semiconductor material.

### CROSS-REFERENCE TO RELATED APPLICATION

This application is a continuation application of International Application PCT/JP2013/076368 filed on Sep. 27, 2013 and designated the U.S., the entire contents of which are incorporated herein by reference.

### FIELD

The embodiments discussed herein are related to a photoelectric conversion device and a fabrication method therefor.

### BACKGROUND

In an organic thin film type solar cell, a photoelectric conversion layer configured from a combination of a p-type organic semiconductor polymer and an n-type organic semiconductor whose example is fullerene is used such that charge separation is performed when an exciton generated by incident light reaches a boundary between the p-type organic semiconductor polymer and the n-type organic semiconductor.

In such an organic thin film type solar cell as just described, a bulk heterojunction (BHJ) type photoelectric conversion layer is frequently used. This is referred to as bulk heterojunction type organic thin film type solar cell.

A bulk heterojunction type photoelectric conversion layer is formed by applying mixed solution, which consists of a p-type organic semiconductor polymer, an n-type organic semiconductor and suitable solvent, and drying the mixed solution. Then, during the course of drying the mixed solution, the p-type organic semiconductor material and the n-type organic semiconductor material individually aggregate spontaneously to cause phase separation, and as a result, a pn junction having a great specific surface area is formed.

It is to be noted that, in order to improve the photoelectric conversion efficiency, a technology for improving the fill factor or a technology for improving the short circuit current is available.

### SUMMARY

According to an aspect of the embodiment, a fabrication method for a photoelectric conversion device includes forming a photoelectric conversion layer, wherein the forming a photoelectric conversion layer includes applying and drying mixed liquid including poly-[N-9′-heptadecanyl-2,7-carbazole-alt-5,5-(4′,7′-di-2-thienyl2′,1′,3′-benzothiadiazle)] as a p-type organic semiconductor material and a fullerene derivative as an n-type organic semiconductor material, which configure a bulk heterojunction, and exposing the dried substance in an atmosphere including vapor of a solvent that dissolves the p-type organic semiconductor material preferentially to the n-type organic semiconductor material.

According to an aspect of the embodiment, a photoelectric conversion device includes a positive electrode, a negative electrode, and a photoelectric conversion layer that is provided between the positive electrode and the negative electrode, includes a p-type organic semiconductor material and an n-type organic semiconductor material, which configure a bulk heterojunction, includes poly-[N-9′-heptadecanyl-2,7-carbazole-alt-5,5-(4′,7′-di-2-thienyl2′,1′,3′-benzothiadiazle)] as the p-type organic semiconductor material, and includes a fullerene derivative as the n-type organic semiconductor material and in which the n-type organic semiconductor material at least partially forms crystal.

The object and advantages of the invention will be realized and attained by means of the elements and combinations particularly pointed out in the claims.

It is to be understood that both the foregoing general description and the following detailed description are exemplary and explanatory and are not restrictive of the invention.

### BRIEF DESCRIPTION OF DRAWINGS

FIG. 1 is a schematic view depicting a configuration of a photoelectric conversion device according to a present embodiment.

FIGS. 2A to 2C are views depicting a structure variation by vapor process in a fabrication method for the photoelectric conversion device according to the present embodiment, wherein FIG. 2A depicts a state before the vapor process is performed, FIG. 2B depicts a course in which the structure during the vapor process is varying and FIG. 2C depicts a state after the vapor process.

FIGS. 3A to 3C are views illustrating a process in which, at a formation step of a photoelectric conversion layer in the fabrication method for a photoelectric conversion device according to the embodiment, a phase separation structure including a region in which an n-type organic semiconductor material is a main constituent, another region in which a p-type organic semiconductor material is a main constituent and crystal of the n-type organic semiconductor material.

FIG. 4 is a view depicting a variation of a photoelectric conversion characteristic with respect to THF processing time of samples of an example 1 from a solar simulator having a radiation illuminance of 100 mW/cm².

FIG. 5 is a view depicting a variation of a photoelectric conversion characteristic with respect to THF processing time of samples of the example 1 under white fluorescent lamp light of an illuminance of 390 Lx and a radiation illuminance of 90 μW/cm².

FIG. 6 is a view depicting I-V curves from a solar simulator having a radiation illuminance 100 mW/cm² of a sample of the example 1 (THF processing time: 1 minute; THF liquid temperature: approximately 30° C.; device temperature: approximately 25° C.; thickness of the photoelectric conversion layer: approximately 80 nm) and a sample of a comparative example 1 (for which a THF process is not performed; thickness of the photoelectric conversion layer: approximately 80 nm).

FIG. 7 is a view depicting I-V curves under white fluorescence lamp light (illuminance: 390 Lx, radiation illuminance: 90 μW/cm²) of a sample of the example 1 (THF processing time: 1 minute; THF liquid temperature approximately 30° C.; device temperature: approximately 25° C.; thickness of the photoelectric conversion layer: approximately 80 nm) and a sample of the comparative example 1 (for which a THF process is not performed; thickness of the photoelectric conversion layer: approximately 80 nm).

FIG. 8 is a view depicting a variation of a photoelectric conversion characteristic with respect to THF processing time of samples of an example 2 from a solar simulator having a radiation illuminance of 100 mW/cm².

FIG. 9 is a view depicting a variation of a photoelectric conversion characteristic with respect to THF processing time of samples of the example 2 under a white fluorescent lamp having an illuminance of 390 Lx and a radiation illuminance of 90 μW/cm².

FIG. 10 is a view depicting I-V curves from a solar simulator having a radiation illuminance of 100 mW/cm² of a sample of the example 2 (THF processing time: 1 minute; THF liquid temperature: approximately 30° C.; device temperature: approximately 25° C.; thickness of the photoelectric conversion layer: approximately 150 nm) and a sample of the comparative example 2 (for which a THF process is not performed; thickness of the photoelectric conversion layer: approximately 150 nm).

FIG. 11 is a view depicting I-V curves under white fluorescence lamp light (illuminance: 390 Lx, radiation illuminance: 90 μW/cm²) of a sample of the example 2 (THF processing time: 1 minute; THF liquid temperature approximately 30° C.; device temperature: approximately 25° C.; thickness of the photoelectric conversion layer: approximately 150 nm) and a sample of the comparative example 2 (for which a THF process is not performed; thickness of photoelectric conversion layer: approximately 150 nm).

FIGS. 12A and 12B are views depicting mapping images as results after an element mapping by electron energy loss spectroscopy is performed for a cross section of a sample of the example 2 (THF processing time: 1 minute; THF liquid temperature: approximately 30° C.; device temperature: approximately 25° C.; thickness of the photoelectric conversion layer: approximately 150 nm). Here, FIG. 12A depicts a mapping image (EELS-C) by the electron energy loss spectroscopy taking carbon atoms as a target and FIG. 12B depicts a mapping image (EELS-S) by the electron energy loss spectroscopy taking sulfur atoms as a target.

FIG. 13 depicts a result when an X-ray photoemission spectroscopy (XPS) analysis is performed for a photoelectric conversion layer of a sample of the example 1 (THF processing time: 1 minute; THF liquid temperature: approximately 30° C.; device temperature: approximately 25° C.; thickness of the photoelectric conversion layer: approximately 80 nm).

FIG. 14 depicts a result when an X-ray photoemission spectroscopy (XPS) analysis is performed for the photoelectric conversion layer of a sample of the comparative example 1 (for which a THF process is not performed; thickness of photoelectric conversion layer: approximately 80 nm).

FIG. 15 is a view depicting an X-ray diffraction profile of the photoelectric conversion layer of a sample of the example 1 (THF processing time: 1 minute; THF liquid temperature: approximately 30° C.; device temperature: approximately 25° C.; thickness of the photoelectric conversion layer: approximately 80 nm) and a sample of the comparative example 1 (for which a THF process is not performed; thickness of photoelectric conversion layer: approximately 80 nm).

FIG. 16 is a view depicting a variation of a photoelectric conversion characteristic with respect to THF processing time pf samples of an example 3 under a white fluorescent lamp having an illuminance of 390 Lx and a radiation illuminance of 90 μW/cm².

FIG. 17 is a view depicting a variation of a photoelectric conversion characteristic with respect to THF processing time of samples of the example 3 from a solar simulator having a radiation illuminance of 100 mW/cm².

FIG. 18 is a view depicting an X-ray diffraction profile of the photoelectric conversion layer of a sample of the example (THF processing time: 3 minute; THF liquid temperature: approximately 25° C.; device temperature: approximately 25° C.; thickness of the photoelectric conversion layer: approximately 150 nm) and a sample of the comparative example 2 (for which a THF process is not performed; thickness of photoelectric conversion layer: approximately 150 nm).

FIG. 19 is a view depicting an X-ray diffraction profile of the photoelectric conversion layer of a sample of the example 5 (THF processing time: 2 minute; THF liquid temperature: approximately 40° C.; device temperature: approximately 40° C.; thickness of the photoelectric conversion layer: approximately 80 nm) and a different sample (THF processing time: 2 minute; THF liquid temperature: approximately 40° C.; device temperature: approximately 25° C.; thickness of the photoelectric conversion layer: approximately 80 nm).

### DESCRIPTION OF EMBODIMENTS

Incidentally, in an organic thin film type solar cell, a high photoelectric conversion efficiency is obtained in a low-illuminance indoor light environment. Therefore, organic thin film type solar cells can coexist well together with Si solar cells, which form a mainstream of solar cells at present, and have high future prospects.

However, in order to obtain a high photoelectric conversion efficiency in a low-illuminance indoor light environment, it is preferable to raise the light absorption efficiency using a photoelectric conversion layer having a great thickness. On the other hand, if only the film thickness of the photoelectric conversion layer is increased simply, the photoelectric conversion efficiency drops by a drop of the fill factor (FF) especially in a high-illuminance solar light environment. Therefore, it is difficult to obtain a high photoelectric conversion efficiency in both of a low-illuminance indoor light environment (low-illuminance condition) and a high-illuminance solar light environment (high-illuminance condition).

Therefore, it is demanded to obtain a high photoelectric conversion efficiency in both of a low-illuminance indoor light environment (low-illuminance condition) and a high-illuminance solar light environment (high-illuminance condition).

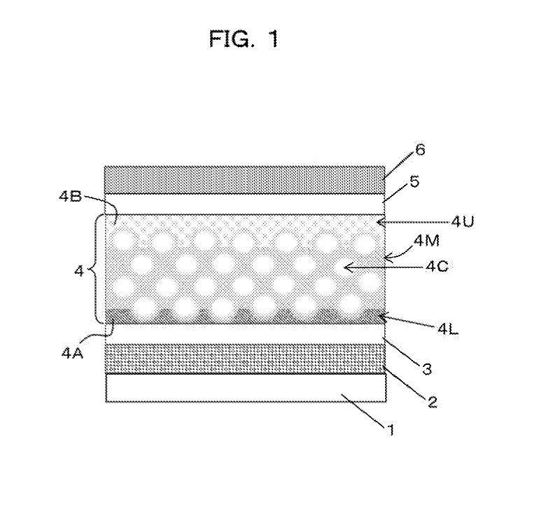

In the following, a photoelectric conversion device and a fabrication method therefor according to an embodiment are described with reference to FIGS. 1 to 19.

The photoelectric conversion device according to the present embodiment is used, for example, as an organic thin film solar cell, particularly, a bulk heterojunction type organic thin film solar cell. Since such a bulk heterojunction type organic thin film solar cell as just described can be fabricated in a printing process, the fabrication cost can be decreased significantly in principle in comparison with a solar cell that forms a mainstream of solar cells at present and in which an inorganic semiconductor is used by stacking in a vacuum process.

As depicted in FIG. 1, the present photoelectric conversion device includes a substrate 1, a positive electrode 2 as a lower electrode, a positive electrode side buffer layer 3, a photoelectric conversion layer 4, a negative electrode side buffer layer 5 and a negative electrode 6 as an upper electrode. It is to be noted that the photoelectric conversion layer 4 is referred to also as photoelectric conversion film.

Here, the substrate 1 is a transparent substrate that transmits incident light therethrough and is, for example, a glass substrate.

The positive electrode 2 is a transparent electrode that is provided on the substrate 1 and transmits incident light therethrough, and is, for example, an ITO (Indium Tin Oxide) electrode. It is to be noted that the positive electrode 2 is hereinafter referred to sometimes as substrate side electrode.

The positive electrode side buffer layer 3 is provided on the positive electrode 2, namely, between the positive electrode 2 and the photoelectric conversion layer 4, and functions as a hole transportation layer. It is to be noted that the positive electrode side buffer layer 3 is referred to also as p-type buffer layer. The positive electrode side buffer layer 3 may be configured so as to include a material in which the energy of the lowest unoccupied molecular orbital (LUMO) is shallower than that of the n-type organic semiconductor material that configures the bulk heterojunction of the photoelectric conversion layer 4 (namely, is near to the vacuum level) and energy of the highest occupied molecular orbital (HOMO) is shallower than that of the p-type organic semiconductor material that configures the bulk heterojunction of the photoelectric conversion layer 4. Here, the positive electrode side buffer layer 3 is a layer including, for example, MoO₃, namely, a layer including molybdenumoxide (VI). It is to be noted that the positive electrode side buffer layer 3 may not be provided. However, where the positive electrode side buffer layer 3 is provided, a more superior characteristic such as, for example, enhancement of the short-circuit current density is obtained.

The photoelectric conversion layer 4 is provided on the positive electrode side buffer layer 3. In particular, the photoelectric conversion layer 4 is provided between the positive electrode side buffer layer 3 and the negative electrode side buffer layer 5. Further, the photoelectric conversion layer 4 is provided between the positive electrode 2 and the negative electrode 6.

The negative electrode side buffer layer 5 is provided on the photoelectric conversion layer 4, namely, between the photoelectric conversion layer 4 and the negative electrode 6, and functions as an electron transport layer. It is to be noted that the negative electrode side buffer layer 5 is referred to also as n-type buffer layer. The negative electrode side buffer layer 5 may be configured so as to include a material in which the energy of the highest occupied molecular orbital is deeper than that of the p-type organic semiconductor material that configures the bulk heterojunction of the photoelectric conversion layer 4 (namely, is far from the vacuum level) and energy of the lowest occupied molecular orbital is deeper than that of the n-type organic semiconductor material that configures the bulk heterojunction of the photoelectric conversion layer 4. Here, the negative electrode side buffer layer 5 is a layer including, for example, TiO_{X}, namely, titanium oxide. It is to be noted that the negative electrode side buffer layer 5 may not be provided. However, where the negative electrode side buffer layer 5 is provided, a more superior characteristic such as, for example, enhancement of the short-circuit current density is obtained.

It is to be noted that a hole blocking layer may be provided in place of the negative electrode side buffer layer 5. In particular, a hole blocking layer may be provided between the photoelectric conversion layer 4 and the negative electrode 6. For example, the hole blocking layer may be configured from a layer including lithium fluoride or metallic calcium. It is to be noted that the hole blocking layer is referred to also as insulating hole blocking layer. While the hole blocking layer may not be provided, by providing the hole blocking layer, a more superior characteristic such as, for example, enhancement of the short-circuit current density or the fill factor (FF) is obtained.

The negative electrode 6 is a metal electrode provided on the negative electrode side buffer layer 5 and is, for example, an aluminum electrode. In short, the negative electrode 6 is provided over the surface of the photoelectric conversion layer 4.

In the present embodiment, the photoelectric conversion layer 4 is a bulk heterojunction type photoelectric conversion layer that includes a p-type organic semiconductor material 4A and an n-type organic semiconductor material 4B that configure a bulk heterojunction, includes, as the p-type organic semiconductor material 4A, poly-[N-9′-heptadecanyl-2, 7-carbazole-alt-5, 5-(4′, 7′-di-2-thienyl 2′, 1′, 3′-benzothiadiazle)] (hereinafter referred to as PCDTBT) that is represented by a chemical formula (1) given below and is an amorphous (non-crystalline) polymer compound, and includes a fullerene derivative as the n-type organic semiconductor material 4B.

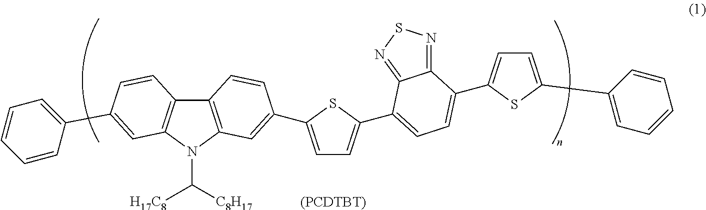

Here, the fullerene derivative as the n-type organic semiconductor material 4B preferably includes one of [6, 6]-phenyl-C₇₁ butyric acid methyl ester (PC71BM produced from C70) represented by a chemical formula (2) given below, [6, 6]-Phenyl-C₆₁ butyric acid methyl ester (PC61BM produced from C60) represented by a chemical formula (3) given below and [6, 6]-Phenyl-C₈₅ butyric acid methyl ester (PC85BM produced from C84) represented by a chemical formula (4) given below or a mixture of the compounds described above (they are hereinafter referred to as PCBM). In particular, the fullerene derivative as the n-type organic semiconductor material 4B may contain any one material selected from the group consisting of [6, 6]-phenyl-C₇₁ butyric acid methyl ester, [6, 6]-Phenyl-C₆₁ butyric acid methyl ester and [6, 6]-Phenyl-C₈₅ butyric acid methyl ester.

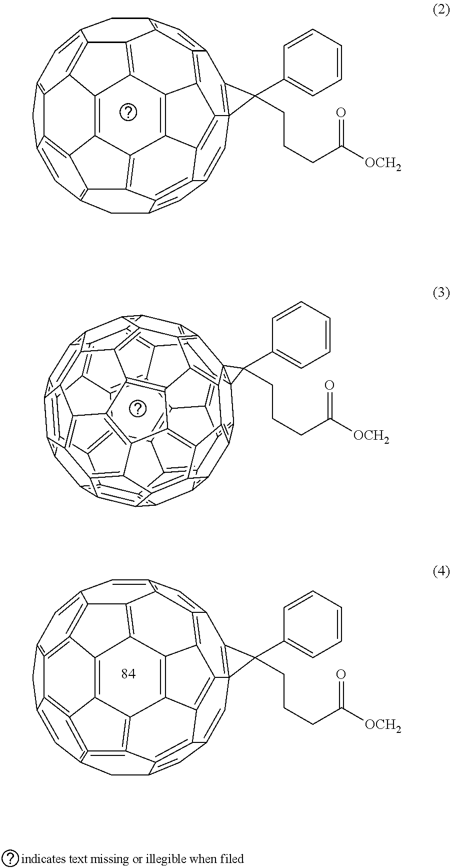

In this case, the photoelectric conversion layer 4 is configured from a mixture of amorphous PCDTBT and PCBM. Here, the reason why the PCDTBT is contained as the p-type organic semiconductor material 4A is that the energy level of the highest occupied molecular orbital is comparatively low and it is easy to obtain a high open circuit voltage. Further, the reason why the PCBM is contained as the n-type organic semiconductor material 4B is that the compound is soluble to a great number of different organic solvents.

It is to be noted that poly-[N-9′-heptadecanyl-2, 7-carbazole-alt-5, 5-(4′, 7′-di-2-thienyl 2′, 1′, 3′-benzothiadiazle)] as the p-type organic semiconductor material 4A is an amorphous polymer compound that has conductivity also in a main chain direction and is not crystalized, namely, an amorphous polymer compound having a low tendency that crystal is formed spontaneously. In such an amorphous polymer compound as just described, different from a crystalline p-type organic semiconductor material in which crystal is formed, the transportability of a carrier can be maintained by the conductivity in the main chain direction even if the crystallinity is low. Therefore, the compound can be used as the p-type organic semiconductor material 4A of the photoelectric conversion layer 4. Further, the p-type organic semiconductor material 4A is referred to sometimes as p-type polymer compound or p-type polymer material.

Further, the fullerene derivative as the n-type organic semiconductor material 4B is a fullerene derivative that is soluble to organic solvent, has a compatibility with the p-type organic semiconductor material 4A and is not crystallized.

Here, while the fullerene derivative as the n-type organic semiconductor material 4B can be crystallized by performing heat treatment of the material as a simple substance at a high temperature (for example, at a high temperature exceeding 100° C.), under coexistence with the p-type organic semiconductor material 4A, the fullerene derivative is not crystallized normally and remains amorphous irrespective of whether or not heat treatment at a high temperature is performed in order to form the photoelectric conversion layer 4. In contrast, in the present embodiment, under coexistence with the p-type organic semiconductor material 4A, the fullerene derivative as the n-type organic semiconductor material 4B in the photoelectric conversion layer 4 forms crystal at least partially as in an example hereinafter described.

In particular, in the present embodiment, by performing a vapor process in which a solvent (here, tetrahydrofuran; THF) that dissolves the p-type organic semiconductor material 4A (here, PCDTBT) preferentially to the n-type organic semiconductor material 4B (here, PCBM) as hereinafter described, the photoelectric conversion layer 4 is configured such that a phase separation structure (structure in which phase separation is advanced; fine structure) of the p-type organic semiconductor material 4A and the n-type organic semiconductor material 4B is provided in the inside of the photoelectric conversion layer 4 and the fullerene derivative as the n-type organic semiconductor material 4B forms crystal at least partially.

In this manner, since the photoelectric conversion layer 4 can be formed at a low temperature such as, for example, a room temperature and growth of a domain structure of the organic semiconductor materials 4A and 4B is suppressed, the photoelectric conversion layer 4 can be configured so as to include the phase separation structure in which the n-type organic semiconductor material 4B and the p-type organic semiconductor material 4A are phase-separated, for example, in a suitable size of the 10 nm order, namely, in a size suitable for charge separation. Further, by forming crystal at least partially from molecules of the fullerene derivative as the n-type organic semiconductor material 4B in the inside of the domain configured from the n-type organic semiconductor material 4B, a state in which electrons are liable to move more readily is established in the inside of the photoelectric conversion layer 4. Further, also in the domain configured from the p-type organic semiconductor material 4A, the purity of the p-type organic semiconductor material 4A is increased and a state in which holes are likely to move readily is established. Here, it is preferable to use a solvent having high dissolution selectivity as the solvent to be used for the vapor process. Consequently, the charge separation efficiency is improved, and, as a result, not only the short circuit current density but also the photoelectric conversion efficiency are improved. Especially, the charge separation efficiency in a room light environment in low illuminance (low-illuminance condition) in which the density of excitons and charge generated in the inside of the photoelectric conversion layer 4 is low is improved, and, as a result, not only the short circuit current density but also the photoelectric conversion efficiency are improved.

Further, in the photoelectric conversion layer 4 of the present embodiment, by performing a vapor process using a solvent (here, THF) that dissolves the p-type organic semiconductor material 4A (here, PCDTBT) preferentially to the n-type organic semiconductor material 4B (here, PCBM) as hereinafter described, a region 4U in which the ratio of the p-type organic semiconductor material 4A is lower than the average ratio is included at the surface side (namely, at the side of the negative electrode 6; at the side at which the negative electrode 6 is to be provided) of the photoelectric conversion layer 4. In this case, the region 4U at the surface side of the photoelectric conversion layer 4 is a region in which an n-type organic semiconductor material (here, PCBM) is a main constituent.

It is to be noted that the ratio of the p-type organic semiconductor material 4A is a proportion or a density of the p-type organic semiconductor material 4A. In particular, the ratio of the p-type organic semiconductor material 4A is a composition ratio (weight ratio) of the p-type organic semiconductor material 4A with respect to the n-type organic semiconductor material 4B. Further, the average ratio is a ratio of the p-type organic semiconductor material 4A in the overall photoelectric conversion layer 4. In particular, the average ratio is a composition ratio (weight ratio) of the p-type organic semiconductor material 4A in the overall photoelectric conversion layer 4 with respect to the n-type organic semiconductor material 4B.

In this manner, by configuring the negative electrode 6 side of the photoelectric conversion layer 4 as a composition gradient structure including the region 4U in which the ratio of the p-type organic semiconductor material 4A is low, namely, a region in which an n-type organic semiconductor material is a main constituent, the probability when electrons and holes are recombination can be lowered to improve the fill factor, and, as a result, the photoelectric conversion efficiency can be improved. Particularly, recombination of carriers generated by a great amount in a solar environment of a high illuminance (high-illuminance condition) can be prevented. Therefore, also where the thickness of the photoelectric conversion layer 4 is made comparatively great in order to obtain a high photoelectric conversion efficiency in a room light environment of a low illuminance, the fill factor in the solar environment of a high illuminance can be enhanced, and, as a result, the photoelectric conversion efficiency can be improved.

Further, in this case, the n-type organic semiconductor material 4B forms substantially spherical aggregated in a region at the positive electrode 2 side with respect to the region 4U in which the n-type organic semiconductor material is a main constituent in the proximity of the negative electrode, and the p-type organic semiconductor material 4A is configured in a mesh form so as to fill up gaps of the aggregates. Further, as depicted by reference character 4C in FIG. 1, the n-type organic semiconductor material 4B forms crystal at least partially. In particular, the photoelectric conversion layer 4 includes a region 4C in which crystal of the n-type organic semiconductor material 4B is formed.

Particularly, it is preferable to configure, by providing the positive electrode side buffer layer 3 (here, buffer layer formed from molybdenum oxide) between the photoelectric conversion layer 4 and the positive electrode 2, the photoelectric conversion layer 4 so as to include a region 4L in which the ratio of the p-type organic semiconductor material 4A (here, PCDTBT) is higher than an average ratio at the side of the positive electrode side buffer layer 3 and another region in which the ratio of the p-type organic semiconductor material 4A is lower than the average ratio at the opposite side of the positive electrode side buffer layer 3 (namely, at the side of the negative electrode 6). In this case, in the photoelectric conversion layer 4, the region at the negative electrode 6 side is a region in which the n-type organic semiconductor material (here, PCBM) is a main constituent while the region at the side of the positive electrode side buffer layer 3 (namely, region at the positive electrode 2 side) is a region in which the p-type organic semiconductor material 4A (here, PCDTBT) is a main constituent. Here, the region 41 in which the ratio of the p-type organic semiconductor material 4A is higher than the average ratio is a region in which the ratio of the n-type organic semiconductor material 4B is lower than the average ratio. Further, the region in which the ratio of the p-type organic semiconductor material 4A is lower than the average ratio is a region in which the ratio of the n-type organic semiconductor material 4B is higher than the average ratio. It is to be noted that the ratio of the n-type organic semiconductor material 4B is a rate or a density of the n-type organic semiconductor material 4B. In other words, the ratio of the n-type organic semiconductor material 4B is a composition ratio (weight ratio) of the n-type organic semiconductor material 4B with respect to the p-type organic semiconductor material 4A. Further, the average ratio is a ratio of the n-type organic semiconductor material 4B in the overall photoelectric conversion layer 4. In particular, the average ratio is a composition ratio (weight ratio) of the n-type organic semiconductor material 4B in the overall photoelectric conversion layer 4 with respect to the p-type organic semiconductor material 4A.

By providing the positive electrode side buffer layer 3 in this manner, the photoelectric conversion layer 4 is obtained which has a composition gradient structure in which the ratio of the p-type organic semiconductor material 4A is high at the positive electrode 2 side and low at the negative electrode 6 side. The photoelectric conversion layer 4 has a composition gradient structure in which the ratio of the p-type organic semiconductor material 4A is high at the positive electrode 2 side and the ratio of the n-type organic semiconductor material 4B is high at the negative electrode 6 side. Consequently, the probability when electrons and holes are recombination can be lowered. In particular, by configuring the photoelectric conversion layer 4 so as to have a composition gradient structure including a region in which the p-type organic semiconductor material is a main constituent at the positive electrode 2 side and a region in which the n-type organic semiconductor material is a main constituent at the negative electrode 6 side, the series resistance of the photoelectric conversion layer 4 can be reduced and the parallel resistance can be increased. Consequently, the fill factor is improved and the photoelectric conversion efficiency is improved. Particularly, recombination of carriers generated by a great amount in a solar environment of high illuminance (high-illuminance condition) can be prevented. Therefore, also where the thickness of the photoelectric conversion layer 4 is made comparatively great in order to obtain a high photoelectric conversion efficiency in a room light environment in low illuminance, the fill factor in the solar environment of a high illuminance can be improved, and, as a result, the photoelectric conversion efficiency can be increased. Then, by performing a vapor process using a solvent (here, THF) that dissolves the p-type organic semiconductor material 4A (here, PCDTBT) preferentially to the n-type organic semiconductor material 4B (here, PCBM) for the photoelectric conversion layer 4 having such a composition gradient structure as described above, the p-type organic semiconductor material 4A included in the region in which the n-type organic semiconductor material is a main constituent at the negative electrode 6 side can be caused to move to the positive electrode 2 side such that the p-type organic semiconductor material 4A can be collected by a greater amount to the positive electrode 2 side, and a more preferable composition gradient structure can be obtained. Consequently, the fill factor can be enhanced further and the photoelectric conversion efficiency can be improved further.

Further, in this case, in an intermediate region 4M sandwiched by the region 41 in the proximity of the positive electrode (positive electrode side buffer layer neighboring region) in which the p-type organic semiconductor material is a main constituent and the region 4U in the proximity of the negative electrode (negative electrode side buffer layer neighboring region) in which the n-type organic semiconductor material is a main constituent, the n-type organic semiconductor material 42 configures substantially spherical aggregates and the p-type organic semiconductor material 4A is configured in a mesh shape so as to fill up gaps between the aggregates. Further, as depicted by reference character 4C in FIG. 1, the n-type organic semiconductor material 4B forms crystal at least partially. In particular, the photoelectric conversion layer 4 includes a region 4C in which crystal of the n-type organic semiconductor material 42 is formed.

Accordingly, in a low illuminance condition, a high photoelectric conversion efficiency is obtained mainly since a high short circuit current density is obtained, and, in a high illuminance condition, a high photoelectric conversion efficiency is obtained mainly since a high fill factor is obtained. In other words, a high photoelectric conversion efficiency can be obtained in both of the room light environment of a low illuminance and the solar environment of a high illuminance.

Further, as described in detail in the description of an example given below, in an X-ray diffraction profile, the photoelectric conversion layer 4 in which the n-type organic semiconductor material 4B described hereinabove forms crystal has both of a diffraction peak corresponding to the (111) plane and another diffraction peak corresponding to the (11-1) plane in an X-ray diffraction profile of the n-type organic semiconductor material 4B as a simple substance. In particular, the photoelectric conversion layer 4 forms crystal of such a degree that both of a diffraction peak corresponding to the (111) plane and another diffraction peak corresponding to the (11-1) plane in an X-ray diffraction profile of the n-type organic semiconductor material 4B as a simple substance.

Incidentally, the photoelectric conversion layer 4 having such a configuration as described above can be obtained as described below.

In particular, mixed liquid (mixed solution) containing an amorphous macromolecular compound (here, PCDTBT) as the p-type organic semiconductor material 4A and a fullerene derivative (here, PCBM) as the n-type organic semiconductor material 4B which configure a bulk heterojunction is applied and dried.

Then, the dried substance is exposed in an atmosphere including vapor of a solvent (here, organic solvent) that dissolves the p-type organic semiconductor material 4A preferentially to the n-type organic semiconductor material 4B. In particular, a vapor process (organic solvent vapor process) is performed in which vapor of a solvent that dissolves the p-type organic semiconductor material 4A preferentially to the n-type organic semiconductor material 4B is caused to act on the dried substance. Here, as the solvent (here, organic solvent) for the vapor process, a solvent may be used in which the solubility of the p-type organic semiconductor material 4A is high and the solubility of the n-type organic semiconductor material 4B is lower than that of the p-type organic semiconductor material 4A. For example, it is preferable to use tetrahydrofuran (THF).

By performing the vapor process for causing vapor of a solvent that dissolves the p-type organic semiconductor material 4A preferentially to the n-type organic semiconductor material 4B to act on the dried substance in this manner, the n-type organic semiconductor material 4B (normally an amorphous n-type organic semiconductor material; here, amorphous PCBM) included in the photoelectric conversion layer 4 is crystalized at least partially. In particular, the photoelectric conversion layer 4 in which the n-type organic semiconductor material 4B described above forms crystal at least partially is formed. Here, the photoelectric conversion layer 4 is formed which has a phase separation structure of the p-type organic semiconductor material 4A and the n-type organic semiconductor material 4B and in which a fullerene derivative as the n-type organic semiconductor material 4B forms crystal at least partially. In other words, in the X-ray diffraction profile, the photoelectric conversion layer 4 having both of a diffraction peak corresponding to the (111) plane and another diffraction peak corresponding to the (11-1) plane in an X-ray diffraction profile of the n-type organic semiconductor material 4B as a simple substance is formed. In this manner, the photoelectric conversion layer 4 having the phase separation structure including crystal of the n-type organic semiconductor material 4B can be formed.

That it is possible to obtain the photoelectric conversion layer 4 having such a configuration as described above by performing the vapor process described above is further described below.

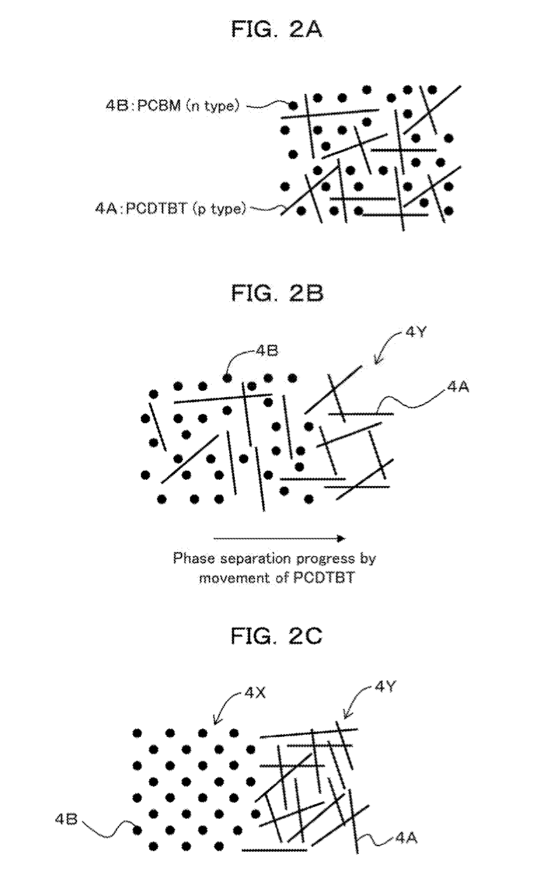

First, before the vapor process described above is performed, a mixed solid (namely, a photoelectric conversion layer for which the vapor process described above was not performed) of the n-type organic semiconductor material 4B (here, PCBM) and the p-type organic semiconductor material 4A (here, PCDTBT) has a bulk heterojunction structure in which the structure regularity is low as depicted in FIG. 2A.

On the other hand, by performing the vapor process described above, molecules of the solvent (here, THF that is an organic solvent) that dissolves the p-type organic semiconductor material 4A preferentially to the n-type organic semiconductor material 4B penetrate the mixed solid of the n-type organic semiconductor material 4B and the p-type organic semiconductor material 4A to dissolve the p-type organic semiconductor material 4A. Consequently, movement of molecules of the p-type organic semiconductor material 4A is facilitated. As a result, formation of the phase separation structure by movement of the p-type organic semiconductor material 4A advances as depicted in FIG. 2B.

As a result, the photoelectric conversion layer 4 having such a configuration as described above, namely, the photoelectric conversion layer 4 that has the phase separation structure of the p-type organic semiconductor material 4A and the n-type organic semiconductor material 4B and in which the n-type organic semiconductor material 4B forms crystal at least partially as depicted in FIG. 2C, is obtained. In particular, after molecules of the solvent (here, THF) that dissolves the p-type organic semiconductor material 4A preferentially to the n-type organic semiconductor material 4B penetrate the mixed solid of the n-type organic semiconductor material 4B and the p-type organic semiconductor material 4A, the p-type organic semiconductor material 4A is dissolved and released from a matrix formed by the n-type organic semiconductor material 4B. As a result, the p-type organic semiconductor material 4A forms a p-type organic semiconductor region 4Y (p-type domain) by aggregation of the p-type organic semiconductor materials 4A in order to reduce the surface energy. On the other hand, the n-type organic semiconductor material 4B is re-arrayed so as to fill up the gaps from which the p-type organic semiconductor material 4A is released to form an n-type organic semiconductor region 4X (n-type domain), and is crystalizes at least partially. In this manner, the photoelectric conversion layer 4 is obtained which has the phase separation structure of the p-type organic semiconductor material 4A and the n-type organic semiconductor material 4B and in which the n-type organic semiconductor material 4B forms crystal at least partially.

It is to be noted that, in this case, the solvent to be used for the vapor process is selected taking dissolution selectivity of the solvent to be used for the vapor process and affinity with the n-type organic semiconductor material 4B into consideration. In particular, by using a solvent having sufficiently high dissolution selectivity as the solvent to be used for the vapor process, the p-type organic semiconductor material 4A can be removed substantially fully from the matrix formed by the n-type organic semiconductor material 4B, and, as a result, molecules of the n-type organic semiconductor material 4B are re-arrayed and form crystal. On the other hand, if the affinity between the solvent to be used for the vapor process and the n-type organic semiconductor material 4B is too low, then the affinity cannot overcome intermolecular force of the n-type organic semiconductor material 4B, and molecules of the n-type organic semiconductor material 4B cannot be re-arrayed and crystallization does not advance.

Where the p-type organic semiconductor material 4A is PCDTBT and the n-type organic semiconductor material 4B is PCBM as in the present embodiment, by using THF as the solvent to be used for the vapor process, the PCDTBT as the p-type organic semiconductor material 4A can be removed substantially fully from the matrix formed by the PCBM as the n-type organic semiconductor material 4B, and the molecules of the n-type organic semiconductor material 42 are re-arrayed and form crystal. In particular, the photoelectric conversion layer 4 is obtained which has a suitable size, for example, of the 10 nm order, namely, a size suitable for charge separation, and has the phase separation structure in which PCBM as the n-type organic semiconductor material 4B and PCDTBT as the p-type organic semiconductor material 4A are phase-separated and in which PCBM as the n-type organic semiconductor material 42 forms crystal. Here, the PCDTBT 4A dissolved by the THF molecules penetrating the inside of the PCDTBT 4A is removed, in order to minimize surface energy, from a mixed state of the PCDTBT 4A and the PCBM 42 and the PCBM 4B is formed in a substantially spherical shape. Further, the PCDTBT 4A configures a meshing form so as to fill up the gaps of the PCBM 4B, and the PCDTBT 4A and the PCBM 42 are phase-separated. In parallel, the array state of the PCBM 4B formed in a substantially spherical shape becomes regular and the PCBM 4B is crystallized at least partially.

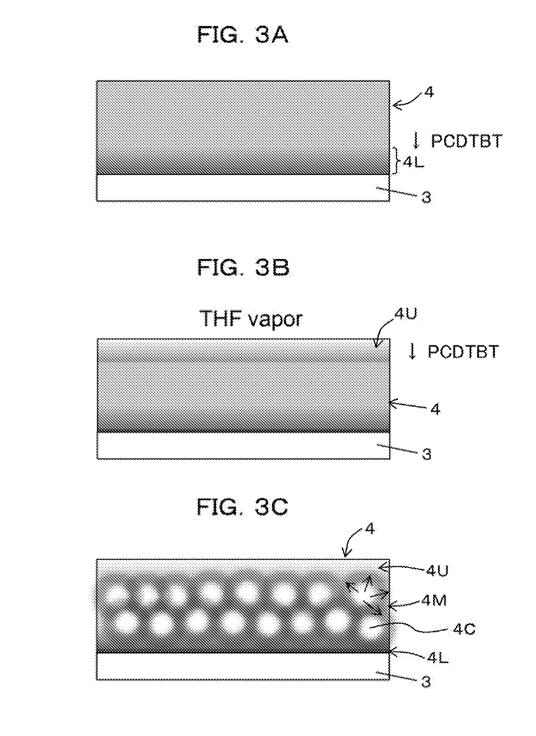

Particularly, as depicted in FIG. 3B, by performing the vapor process described above, molecules (here, THF molecules) of the solvent penetrate and, in order to minimize the surface energy, the p-type organic semiconductor material 4A that is dissolved and becomes easy to move moves from the surface side toward the inside in which the p-type organic semiconductor material 4A exists. As a result, the photoelectric conversion layer 4 having the region 4U in which the ratio of the p-type organic semiconductor material 4A is lower than an average ratio is formed at the surface side (namely, at the upper side). In particular, the photoelectric conversion layer 4 having a region in which the n-type organic semiconductor material 42 is a main constituent is formed at the surface side. Here, the negative electrode 6 (refer to FIG. 1) is formed over the surface of the photoelectric conversion layer 4 having the region 4U in which the ratio of the p-type organic semiconductor material 4A is lower than the average ratio at the surface side. Therefore, the photoelectric conversion layer 4 including the region 4U in which the ratio of the p-type organic semiconductor material 4A is lower than the average ratio is formed at the negative electrode 6 side. In this manner, the photoelectric conversion layer 4 can be formed which has the phase separation structure including crystal of the n-type organic semiconductor material 4B and the composition gradient structure.

Further, where the positive electrode 2 is formed and the positive electrode side buffer layer 3 (here, formed from molybdenum oxide having high affinity with PCDTBT) is further formed before the photoelectric conversion layer 4 is formed, the p-type organic semiconductor material 4A is preferentially absorbed to (stacked on) the surface of the positive electrode side buffer layer 3 when mixed liquid containing the p-type organic semiconductor material 4A and the n-type organic semiconductor material 4B is applied. Consequently, as depicted in FIG. 3A, the ratio of the p-type organic semiconductor material 4A in a region (buffer layer neighboring region; region at the positive electrode 2 side) contacting with the positive electrode side buffer layer 3 of the photoelectric conversion layer 4 becomes higher than the average ratio and besides the ratio of the p-type organic semiconductor material 4A in the region at the negative electrode 6 side becomes lower than the average ratio in comparison with the ratio in the region contacting with the positive electrode side buffer layer 3 of the photoelectric conversion layer 4. In particular, the region 4L in which the ratio of the p-type organic semiconductor material 4A is higher than the average ratio and the region in which the ratio of the p-type organic semiconductor material 4A is lower than the average ratio (namely, the region in which the ratio of the n-type organic semiconductor material 4B is higher than the average ratio) are formed at the same time. In this manner, the photoelectric conversion layer 4 including the region 41, in which the ratio of the p-type organic semiconductor material 4A is higher than the average ratio at the side of the positive electrode side buffer layer 3 and the region in which the ratio of the p-type organic semiconductor material 4A is lower than the average ratio at the opposite side to the positive electrode side buffer layer 3 is formed. Then, by performing the vapor process described above for the surface of the mixture film dried in such a state as described above, molecules (here, THF molecules) of the solvent penetrate to dissolve the p-type organic semiconductor material 4A to facilitate movement of the same, and, in order to minimize the surface energy, the p-type organic semiconductor material 4A moves from the surface side toward the inside in which the p-type organic semiconductor material 4A exists. As a result, as depicted in FIG. 3B, the photoelectric conversion layer 4 having the region 4U in which the ratio of the p-type organic semiconductor material 4A is lower than the average ratio at the surface side (namely, at the upper side; at the negative electrode 6 side) is formed. In other words, the photoelectric conversion layer 4 having the region in which the n-type organic semiconductor material 42 is a main constituent at the surface side is formed. In this manner, as depicted in FIG. 3C, the region 4U in which the ratio of the p-type organic semiconductor material 4A is low is formed at the surface side (namely, at the negative electrode 6 side) of the photoelectric conversion layer 4 and the region 4L in which the ratio of the p-type organic semiconductor material 4A is high is formed at the side of the positive electrode side buffer layer 3. Further, a structure including the region 4C in which the n-type organic semiconductor material 4B configures substantially spherical aggregates and the p-type organic semiconductor material 4A configures a mesh form so as to fill up the gaps between the substantially spherical aggregates and besides crystal of the n-type organic semiconductor material 4B is formed is formed in the intermediate region 4M between the region 4U in which the ratio of the p-type organic semiconductor material 4A is low and the region 4L in which the ratio of the p-type organic semiconductor material 4A is high. Particularly, since the p-type organic semiconductor material 4A dissolved by molecules (here, THF molecules) of the solvent penetrating the inside thereof and released from a mixed state of the n-type organic semiconductor material 4B and the p-type organic semiconductor material 4A can reduce the surface energy if a domain integrally with the p-type organic semiconductor material 4A absorbed to the surface of the positive electrode side buffer layer 3 is formed, a greater amount of the p-type organic semiconductor materials 4A aggregates on the positive electrode side buffer layer 3. By providing the positive electrode side buffer layer 3 in this manner, the photoelectric conversion layer 4 having a more preferable composition gradient structure is formed. In this manner, the photoelectric conversion layer (charge separation layer) 4 having the phase separation structure including crystal of the n-type organic semiconductor material 4B and a more preferable composition gradient structure can be formed.

Now, the fabrication method for a photoelectric conversion device according to the present embodiment is described in detail.

First, a positive electrode 2 (transparent electrode) is formed on a substrate 1 (transparent substrate).

Then, a positive electrode side buffer layer 3 (here, a layer containing MoO₃) is formed on the positive electrode 2.

Then, a photoelectric conversion layer 4 is formed on the positive electrode side buffer layer 3.

In particular, mixed liquid containing an amorphous polymer compound (here, PCDTBT) as the p-type organic semiconductor material 4A and a fullerene derivative (here, PCBM) as the n-type organic semiconductor material 4B is applied (applying step) on the surface of the positive electrode side buffer layer 3 formed on the positive electrode 2 and is dried (drying step).

Then, the dried substance is exposed in an atmosphere including vapor of a solvent (here, THF as an organic solvent) that dissolves the p-type organic semiconductor material 4A preferentially to the n-type organic semiconductor material 4B. This is referred to as vapor process, organic solvent vapor process or THF process. Consequently, a photoelectric conversion layer 4 having a phase separation structure including crystal of the n-type organic semiconductor material 42 and a more preferable composition gradient structure is formed as described above.

Then, a hole blocking layer (here, a layer containing lithium fluoride) that functions also as the negative electrode side buffer layer 5 is formed on the photoelectric conversion layer 4.

Thereafter, a negative electrode 6 (metal electrode) is formed on the negative electrode side buffer layer 5.

Then, the assembly is encapsulated in, for example, a nitrogen atmosphere, and thereby a photoelectric conversion device is completed.

Accordingly, with the photoelectric conversion device and the fabrication method for the photoelectric conversion device according to the present embodiment, there is an advantage that a high photoelectric conversion efficiency can be obtained in both of a room light environment of a low illuminance (low illuminance condition) and a solar environment of a high illuminance (high illuminance condition). Further, with the photoelectric conversion device and the fabrication method for the photoelectric conversion device according to the present embodiment, a photoelectric conversion device by which a high photoelectric conversion efficiency is obtained in both of a room light environment of a low illuminance and a solar environment of a high illuminance can be fabricated easily.

It is to be noted that the present invention is not limited to the embodiment specifically described above, and various modifications can be made without departing from the scope of the present invention.

For example, while the drying step in the embodiment described above is performed after the applying step, the present invention is not limited to this, and, for example, the applying step and the drying step may be performed in parallel by one step. In particular, although, in the embodiment described above, applied mixed liquid is dried at a step after the mixed liquid is applied, for example, applying and drying of the mixed liquid may be performed in parallel by one step.

Further, while the embodiment is described above taking, as an example, a case where the photoelectric conversion device is used for an organic thin solar battery, the present invention is not limited to this, and the photoelectric conversion device can be used also in a sensor of an image pickup apparatus such as, for example, a camera.

### EXAMPLE

The present invention is described below in more detail in connection with an example. However, the present invention is not limited by the example described below.

In the present example, the photoelectric conversion device was produced in the following manner.

First, an ITO electrode (positive electrode; lower electrode) having a film thickness of approximately 150 nm was formed on a glass substrate.

Then, a molybdenum oxide (VI) layer (positive electrode side buffer layer) having a film thickness of approximately 6 nm was formed by vacuum deposition on the overall area of the ITO electrode as the positive electrode.

Then, the glass substrate on which the ITO electrode and the molybdenum oxide (VI) layer were formed was transferred to a glove box in the inside of which nitrogen is filled, and monochlorobenzene solution (mixed solution; concentration: approximately 2 weight %) containing PCDTBT as a p-type organic semiconductor material and PCBM as an n-type organic semiconductor material (here, [6, 6]-phenyl-C₇₁-butyric acid methyl ester; hereinafter referred to as PC71BM) at a ratio by weight of 1:3 was applied by spin coating deposition at approximately 25° C. (room temperature) and was dried.

Then, the dried substance was left (exposed) in a saturation atmosphere including vapor of THF as a solvent that dissolves the p-type organic semiconductor material preferentially to the n-type organic semiconductor material using the TFT as a vapor source with the liquid temperature set to approximately 30° C. Here, the substance dried after the mixed liquid was applied thereto as described above was transferred to and left in a closed container in which a saturation atmosphere of THF was produced by using THF of a liquid temperature of approximately 30° C. as a vapor source in the state where the temperature (device temperature) of the substance was kept at approximately 25° C. In other words, a THF process (vapor process) was performed.

A photoelectric conversion layer having a thickness of approximately 80 nm was formed in this manner.

Then, a lithium fluoride layer (hole blocking layer) having a film thickness of approximately 1 nm was formed on the photoelectric conversion layer formed and exposed in such a manner as described above without performing heat treatment. Here, a lithium fluoride layer having a film thickness of approximately 1 nm was formed on the photoelectric conversion layer taken out from the sealing container described above and formed and exposed in such a manner as described above.

Thereafter, an aluminum electrode (negative electrode; upper electrode) having a thickness of approximately 150 nm was formed by vacuum deposition on the lithium fluoride layer as a hole blocking layer.

Then, a photoelectric conversion device was produced by encapsulating in an oxygen atmosphere.

Here, a plurality of photoelectric conversion devices (samples; thickness of the photoelectric conversion layer: approximately 80 nm) were produced by setting the liquid temperature of the THF to approximately 30° C., setting the device temperature to approximately 25° C. and changing the time period (THF processing time period; exposing time period) for leaving the product in the THF saturation atmosphere. Each of the photoelectric conversion devices just described is hereinafter referred to as sample of the example 1.

Further, a photoelectric conversion device was produced similarly to the samples of the example 1 described above without performing the THF process. The photoelectric conversion device produced in this manner is hereinafter referred to as sample of a comparative example 1.

Further, a plurality of photoelectric conversion devices in which the thickness of the photoelectric conversion layer was varied to approximately 150 nm in comparison with the samples of the example 1 were produced by setting the liquid temperature of the THF to approximately 30° C., setting the device temperature to approximately 25° C. and changing the THF processing time period. Each of the photoelectric conversion devices just described is hereinafter referred to sometimes as sample of an example 2.

Further, a photoelectric conversion device was produced similarly to the samples of the example 2 described above without performing the THF process. The photoelectric conversion device just described is hereinafter referred to as sample of a comparative example 2.

Further, a plurality of photoelectric conversion devices (samples; thickness of the photoelectric conversion layer: approximately 150 nm) were produced by setting the liquid temperature of the THF to approximately 25° C., setting the device temperature to approximately 25° C. and changing the THF processing time period. Each of the photoelectric conversion devices just described above is hereinafter referred to as sample of an example 3.

Further, a plurality of photoelectric conversion devices in which the thickness of the photoelectric conversion layer was varied to approximately 80 nm in comparison with the samples of the example 3 were produced by setting the liquid temperature of the THF to approximately 25° C., setting the device temperature to approximately 25° C. and changing the THF processing time period. Each of the photoelectric conversion devices just described above is hereinafter referred to as sample of an example 4.

Further, a photoelectric conversion device in which the thickness of the photoelectric conversion layer was approximately 80 nm was produced by setting the THF processing time period to two minutes, setting the liquid temperature of the THF to approximately 40° C. and setting the device temperature to approximately 40° C. The photoelectric conversion device just described is hereinafter referred to as sample of an example 5.

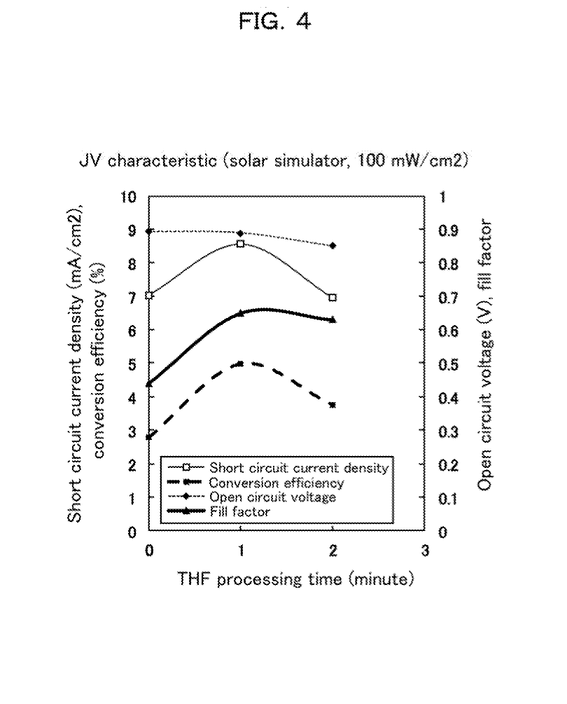

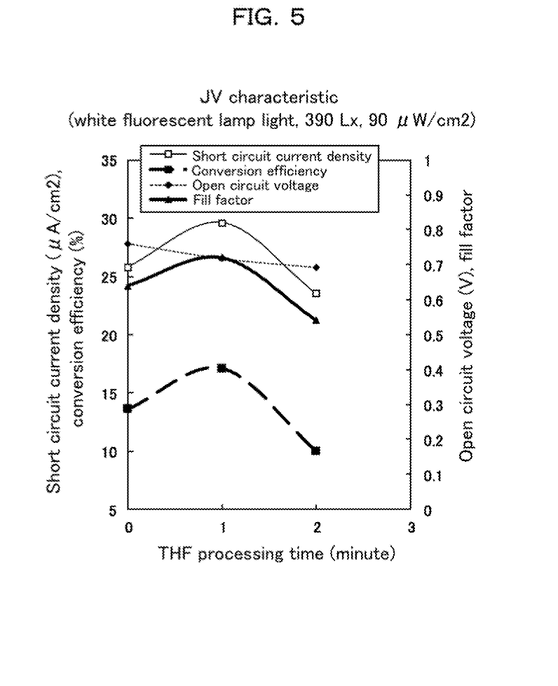

Here, FIG. 4 depicts variations of a photoelectric conversion characteristic (JV characteristic; photoelectric conversion parameter) with respect to the THF processing time period of the samples of the example 1 and the comparative example 1 from a solar simulator wherein the AM (air mass) is 1.5 and the irradiation illuminance is 100 mW/cm². Further, FIG. 5 depicts variations of a photoelectric conversion characteristic (JV characteristic; photoelectric conversion parameter) with respect to the THF processing time period of the samples of the example 1 and the comparative example 1 under a white fluorescent lamp having an illuminance of 390 Lx and an irradiation illuminance 90 μW/cm².

First, as depicted in FIG. 4, in the samples of the example 1 for which the THF process was performed (THF processing time period: 1 minute and 2 minutes), the fill factor and the short circuit current density exhibit maximum values with the THF processing time period of 1 minute. Thus, the samples of the example 1 indicated improvement in fill factor and short circuit current density in comparison with the sample of the comparative example 1 for which the THF process was not performed (THF processing time period: 0 minute). As a result, the samples of the example 1 for which the THF process was performed (THF processing time period: 1 minute and 2 minutes) was improved in photoelectric conversion efficiency in comparison with the sample of the comparative example 1 for which the THF process was not performed (THF processing time period: 0 minute). Particularly, the best photoelectric conversion efficiency was obtained with the THF processing time period of 1 minute. In this manner, the samples of the example 1 for which the THF process was performed (THF processing time period: 1 minute and 2 minutes) were improved in photoelectric conversion efficiency in a solar environment of a high illuminance (high illuminance condition) in comparison with the sample of the comparative example 1 for which the THF process was not performed (THF processing time period: 0 minute). Particularly, the best photoelectric conversion efficiency was obtained with the THF processing time period of 1 minute.

Further, as depicted in FIG. 5, in the sample of the example 1 for which the THF process was performed within a time period of approximately 90 seconds (here, THF processing time period: 1 minute), the fill factor and the short circuit current density exhibit maximum values with the THF processing time period of 1 minute and were improved in comparison with the sample of the comparative example 1 for which the THF process was not performed (THF processing time period: 0 minute). As a result, the sample of the example 1 for which the THF process was performed within a time period of approximately 90 seconds (here, THF processing time period: 1 minute) was improved in photoelectric conversion efficiency in comparison with the sample of the comparative example 1 for which the THF process was not performed (THF processing time period of 0 minute). Particularly, the best photoelectric conversion efficiency was obtained with the THF processing time period of 1 minute. In this manner, the sample of the example 1 for which the THF process was performed within a time period of approximately 90 seconds (here, THF processing time period: 1 minute) was improved in photoelectric conversion efficiency in a room light environment of a low illuminance (low illuminance condition) in comparison with the sample of the comparative example 1 for which the THF process was not performed (THF processing time period: minute). Particularly, the best photoelectric conversion efficiency was obtained with the THF processing time period of 1 minute.

In this manner, by performing the THF process within a time period of approximately 90 seconds, the photoelectric conversion efficiency was improved in both of a room light environment of a low illuminance and a solar environment of a high illuminance in comparison with an alternative case where the THF process was not performed. Particularly, the best photoelectric conversion efficiency was obtained with the THF processing time period of 1 minute in both of a room light environment of a low illuminance and a solar environment of a high illuminance.

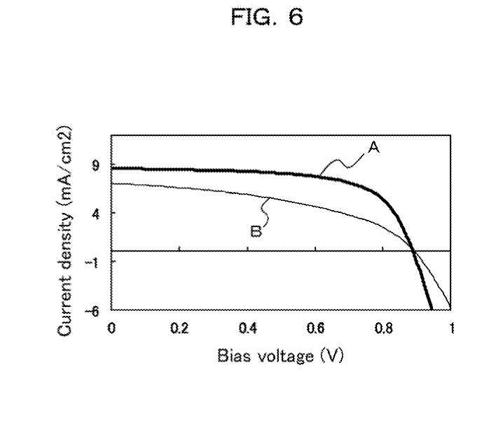

Here, FIG. 6 depicts I-V curves (J-V curves) from a solar simulator (AM (airmass): 1.5, irradiation illuminance: 100 mW/cm²) of the sample of the example 1 (THF processing time period: 1 minute; THF liquid temperature: approximately 30° C., device temperature: approximately 25° C.; thickness of photoelectric conversion layer: approximately 80 nm) and the sample of the comparative example 1 (no THF process; thickness of photoelectric conversion layer: approximately 80 nm).

As depicted in FIG. 6, under a high illuminance condition in a solar simulator, the sample of the example 1 exhibits such an I-V curve as indicated by a solid line A in FIG. 6, and the sample of the comparative example 1 exhibits such an I-V curve as indicated by a solid line B in FIG. 6. In particular, in the sample of the example 1, the open circuit voltage (Voc), short circuit current density (Jsc), fill factor (FF) and photoelectric conversion efficiency, which are IV parameters in the solar simulator, were approximately 0.889 V, approximately 8.56 mA/cm², approximately 0.65 and approximately 5.0%, respectively. On the other hand, in the sample of the comparative example 1, the open circuit voltage (Voc), short circuit current density (Jsc), fill factor (FF) and photoelectric conversion efficiency were approximately 0.893 V, approximately 7.03 mA/cm², approximately 0.44 and approximately 2.8%, respectively. It is to be noted that the photoelectric conversion efficiency can be calculated by an expression of photoelectric conversion efficiency=(Voc×Jsc×FF)/irradiation illuminance of incident light×100. In this manner, the sample of the example 1 was improved in short circuit current density (Jsc) and fill factor (FF) in comparison with the sample of the comparative example 1. As a result, the photoelectric conversion efficiency was improved. In other words, by performing the THF process for 1 minute at the THF liquid temperature of approximately 30° C. and the device temperature of approximately 25° C., the short circuit current density (Jsc) and the fill factor (FF) were improved, and, as a result, the photoelectric conversion efficiency was increased.

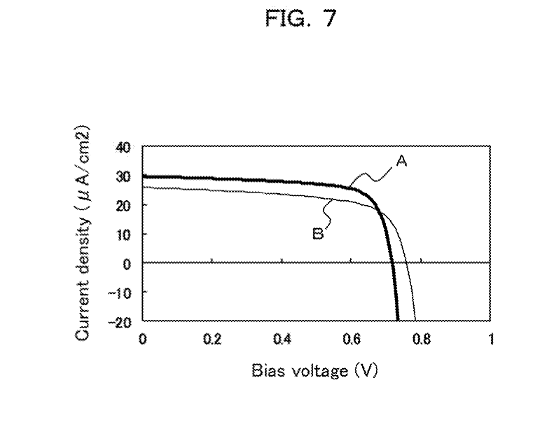

Meanwhile, FIG. 7 depicts I-V curves (J-V curves) under white fluorescent lamp light (illuminance: 390 Lx, irradiation illuminance: 90 μW/cm²) of the sample of the example 1 (THF processing time period: 1 minute; THF liquid temperature: approximately 30° C., device temperature: approximately 25° C.; thickness of photoelectric conversion layer: approximately 80 nm) and the sample of the comparative example 1 (no THF process; thickness of photoelectric conversion layer: approximately 80 nm).

As depicted in FIG. 7, under white fluorescent lamplight, namely, under a low illuminance condition, the sample of the example 1 indicates such an I-V curve as indicated by a solid line A in FIG. 7. Meanwhile, the sample of the comparative example 1 indicates such an I-V curve as indicated by a solid line B in FIG. 7. In particular, in the sample of the example 1, the open circuit voltage (Voc), short circuit current density (Jsc), fill factor (FF), maximum power density (Pmax) and photoelectric conversion efficiency, which are IV parameters in the white fluorescent lamp, were approximately 0.718 V, approximately 29.6 μA/cm², approximately 0.72, approximately 15.3 μW/cm² and approximately 17%, respectively. On the other hand, in the sample of the comparative example 1, the open circuit voltage (Voc), short circuit current density (Jsc), fill factor (FF), maximum power density (Pmax) and photoelectric conversion efficiency were approximately 0.760 V, approximately 25.8 μA/cm², approximately 0.64, approximately 12.6 μW/cm² and approximately 14%, respectively. It is to be noted the fill factor is defined by (Pmax)/(Voc×Jsc). In this manner, in the sample of the example 1, the short circuit current density (Jsc) and the fill factor (FF) were improved in comparison with those of the sample of the comparative example 1, and, as a result, the photoelectric conversion efficiency was improved. In short, by performing the THF process for 1 minute at the THF liquid temperature of approximately 30° C. and the device temperature of approximately 25° C., the short circuit current density (Jsc) and the fill factor (FF) were improved, and, as a result, the photoelectric conversion efficiency was improved.

In this manner, by performing the THF process for 1 minute at the THF liquid temperature of approximately 30° C. and the device temperature of approximately 25° C., the short circuit current density (Jsc) and the fill factor (FF) were improved under both of a high illuminance condition and a low illuminance condition, and, as a result, the photoelectric conversion efficiency was increased.

It is to be noted that, in the photoelectric conversion device produced as in the example 1, when the THF process was performed within a time period of approximately 90 seconds, the fill factor, short circuit current density and photoelectric conversion efficiency were improved in a room light environment of a low illuminance in comparison with those in the case where the THF process was not performed. However, if conditions such as, for example, the thickness, temperature and density change, then the photoelectric conversion efficiency can be improved also where the THG process is performed over a longer time period.

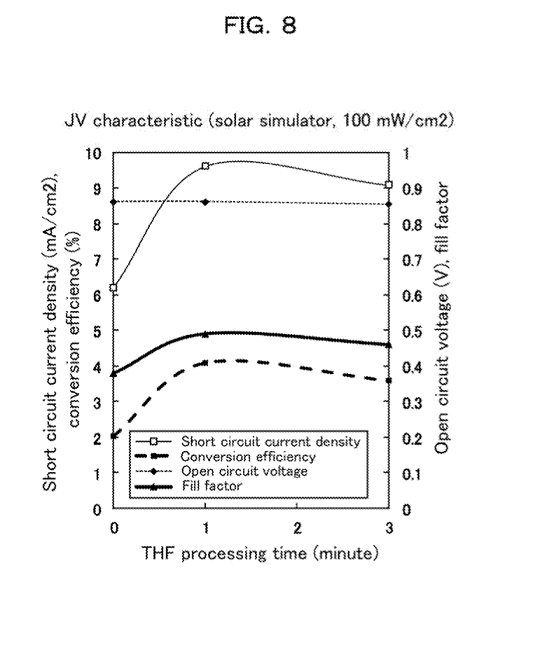

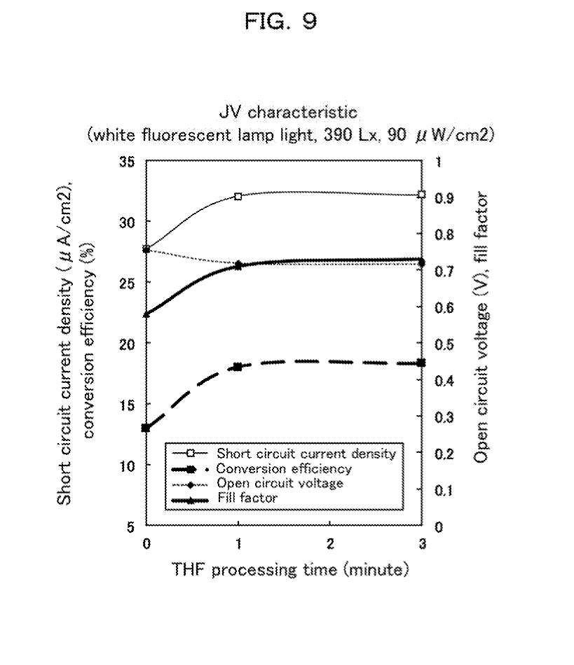

Here, FIG. 8 depicts variation of a photoelectric conversion characteristic (JV characteristic; photoelectric conversion parameter) with respect to the THF processing time period of the samples of the example 2 and the comparative example 2 from a solar simulator wherein the AM (air mass) is 1.5 and the irradiation illuminance is 100 mW/cm². Meanwhile, FIG. 9 depicts a variation of a photoelectric conversion characteristic (JV characteristic; photoelectric conversion parameter) with respect to the THF processing time period of the samples of the example 2 and the comparative example 2 under a white fluorescent lamp wherein the illuminance was 390 Lx and the irradiation illuminance was 90 μW/cm².

First, as depicted in FIG. 8, in the samples of the example 2 (photoelectric conversion time period: 1 minute to 3 minutes) in which the thickness of the photoelectric conversion layer was approximately 150 nm and for which the THF process was performed, similarly to the samples of the example 1 described hereinabove (photoelectric conversion time period: 1 minute and 2 minutes) described above, the fill factor and the short circuit current density exhibit maximum values with the THF processing time period of 1 minute and were improved in comparison with the sample of the comparative example 2 (THF processing time period: 0 minute) in which the thickness of the photoelectric conversion layer was approximately 150 nm and for which the THF process was not performed. As a result, the samples of the example 2 (photoelectric conversion time period: 1 minute to 3 minutes) in which the thickness of the photoelectric conversion layer was approximately 150 nm and for which the THF process was performed were improved, similarly to the samples of the example 1 described hereinabove (photoelectric conversion efficiency: 1 minute and 2 minutes), in photoelectric conversion efficiency in comparison with the sample of the comparative example 2 in which the thickness of the photoelectric conversion layer was approximately 150 nm and for which the THF process was not performed. Particularly, the best photoelectric conversion efficiency was obtained with the THF processing time period of 1 minute. In this manner, the samples of the example 2 in which the thickness of the photoelectric conversion layer was approximately 150 nm and for which the THF process was performed (photoelectric conversion efficiency: 1 minute to 3 minutes) were improved, similarly to the samples of the example 1 described hereinabove (photoelectric conversion efficiency: 1 minute and 2 minutes), in photoelectric conversion efficiency in a solar environment of a high illuminance in comparison with the sample of the comparative example 2 in which the thickness of the photoelectric conversion layer was approximately 150 nm and for which the THF process was not performed (THF processing time period: 0 minute). Particularly, the best photoelectric conversion efficiency was obtained with the THF processing time period of 1 minute

Further, as depicted in FIG. 9, in the samples of the example 2 in which the thickness of the photoelectric conversion layer was approximately 150 nm and for which the THF process was performed (photoelectric conversion efficiency: 1 minute to 3 minutes), the fill factor and the short circuit current density were improved in comparison with those of the sample of the comparative example 2 for which the THF process was not performed (THF processing time period: 0 minute). As a result, the samples of the example 2 in which the thickness of the photoelectric conversion layer was approximately 150 nm and for which the THF process was performed (photoelectric conversion efficiency: 1 minute to 3 minutes) were improved in photoelectric conversion efficiency in comparison with the sample of the comparative example 2 in which the thickness of the photoelectric conversion layer was approximately 150 nm and for which the THF process was not performed (THF processing time period: 0 minute). Particularly, a good photoelectric conversion efficiency was obtained with the THF processing time period of 1 minute, and degradation of the photoelectric conversion efficiency was not found even if the THF processing time period was extended from 1 minute to 3 minutes. In this manner, the samples of the example 2 in which the thickness of the photoelectric conversion layer was approximately 150 nm and for which the THF process was performed (photoelectric conversion efficiency: 1 minute to 3 minutes) were improved in photoelectric conversion efficiency in a room light environment of a low illuminance in comparison with the sample of the comparative example 2 in which the thickness of the photoelectric conversion layer was approximately 150 nm and for which the THF process was not performed (THF processing time period: 0 minute). Particularly, a good photoelectric conversion efficiency was obtained with the THF processing time period of 1 minute, and even if the THF processing time period was extended from 1 minute to 3 minutes, the photoelectric conversion efficiency did not degrade. In short, with the samples of the example 2 in which the thickness of the photoelectric conversion layer was changed to approximately 150 nm in comparison with the samples of the example 1 described above, a good photoelectric conversion efficiency was obtained in the THF processing time period of 1 minute in a room light environment of a low illuminance and even if the THF processing time period was extended from 1 minute to 3 minutes, the photoelectric conversion efficiency did not degrade.

In this manner, by increasing the thickness of the photoelectric conversion layer 4 and performing the THF process irrespective of the processing time period, the photoelectric conversion efficiency is improved in both of a room light environment of a low illuminance and a solar environment of a high illuminance in comparison with that in an alternative case in which the THF process is not performed. Particularly, the best photoelectric conversion efficiency is obtained with the THF processing time period of 1 minute in both of a room light environment of a low illuminance and a solar environment of a high illuminance.

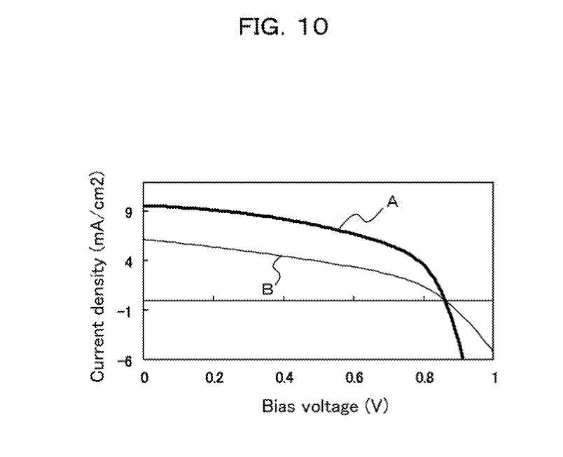

Here, FIG. 10 depicts I-V curves (J-V curves) from a solar simulator (AM (air mass): 1.5, irradiation illuminance: 100 mW/cm²) of the sample of the example 2 (THF processing time period: 1 minute; THF liquid temperature: approximately 30° C., device temperature: approximately 25° C.; thickness of the photoelectric conversion layer: approximately 150 nm) and the sample of the comparative example 2 (no THF process; thickness of photoelectric conversion layer: approximately 150 nm).

As depicted in FIG. 10, under a high illuminance condition in a solar simulator, the sample of the example 2 indicate such an I-V curve as indicated by a solid line A in FIG. 10 and the sample of the comparative example 2 indicates such an I-V curve as indicated by a solid line B in FIG. 10. In particular, in the sample of the example 2, the open circuit voltage (Voc), short circuit current density (Jsc), fill factor (FF) and photoelectric conversion efficiency, which are IV parameters in a solar simulator, were approximately 0.861 V, approximately 9.61 mA/cm², approximately 0.49 and approximately 4.1%, respectively. On the other hand, in the sample of the comparative example 2, the open circuit voltage (Voc), short circuit current density (Jsc), fill factor (FF) and photoelectric conversion efficiency were approximately 0.861 V, approximately 6.19 mA/cm², approximately 0.38 and approximately 2.0%, respectively. In this manner, in the sample of the example 2, the short circuit current density (Jsc) and the fill factor (FF) were improved in comparison with the sample of the comparative example 2, and, as a result, the photoelectric conversion efficiency was improved. In particular, also where the thickness of the photoelectric conversion layer was increased, by performing the THF process for 1 minute, the short circuit current density (Jsc) and the fill factor (FF) were improved, and, as a result, the photoelectric conversion efficiency was improved.

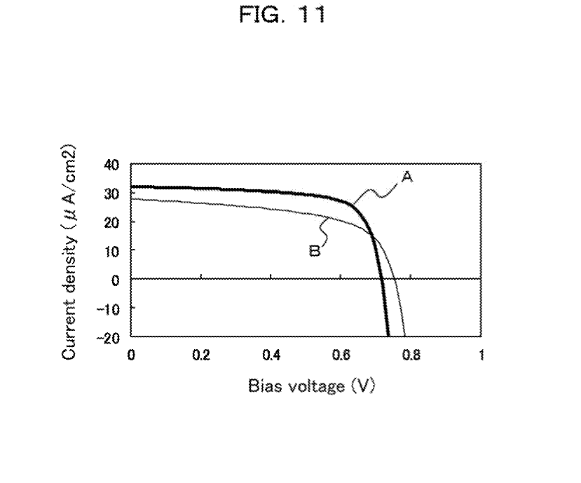

Further, FIG. 11 depicts an I-V curve (J-V curve) under white fluorescent lamp light (illuminance: 390 Lx, irradiation illuminance: 90 μW/cm²) of the sample of the example 2 (THF processing time period: 1 minute; THF liquid temperature: approximately 30° C., device temperature: approximately 25° C.; thickness of the photoelectric conversion layer: approximately 150 nm) and the sample of the comparative example 2 (no THF process; thickness of the photoelectric conversion layer: approximately 150 nm).

As depicted in FIG. 11, under white fluorescent lamp light, namely, under a low illuminance condition, the sample of the example 2 indicates such an I-V curve as indicated by a solid line A in FIG. 11 and, the sample of the comparative example 2 indicates such an I-V curve as indicated as indicated by a solid line B in FIG. 11. In particular, in the sample of the example 2, the open circuit voltage (Voc), short circuit current density (Jsc), fill factor (FF), maximum power density (Pmax) and photoelectric conversion efficiency, which are IV parameters of the white fluorescent lamp, were approximately 0.718 V, approximately 32.1 μA/cm², approximately 0.71, approximately 16.3 μW/cm² and approximately 18%, respectively. On the other hand, in the sample of the comparative example 2, the open circuit voltage (Voc), short circuit current density (Jsc), fill factor (FF), maximum power density (Pmax) and photoelectric conversion efficiency were approximately 0.754 V, approximately 27.7 μA/cm², approximately 0.58, approximately 12.1 μW/cm² and approximately 13%, respectively. In this manner, the sample of the example 2 was improved in short circuit current density (Jsc) and fill factor (FF) in comparison with the sample of the comparative example 2, and, as a result, the photoelectric conversion efficiency was improved. In particular, also where the thickness of the photoelectric conversion layer is increased, by performing the THF process for 1 minute at the THF liquid temperature of approximately 30° C. and the device temperature of approximately 25° C., the short circuit current density (Jsc) and the fill factor (FF) were improved, and, as a result, the photoelectric conversion efficiency was increased. Further, the sample of the example 2 was improved in short circuit current density (Jsc) under a low illuminance condition in comparison with the sample of the example 1, and, as a result, the photoelectric conversion efficiency was improved.

In this manner, by performing the THF process for 1 minute at the THF liquid temperature of approximately 30° C. and the device temperature of approximately 25° C., also where the thickness of the photoelectric conversion layer was increased, under both conditions of a high illuminance condition and a low illuminance condition, the short circuit current density (Jsc) and the fill factor (FF) were improved and, as a result, the photoelectric conversion efficiency was increased. Further, by making the photoelectric conversion layer thicker, the short circuit current density (Jsc) was enhanced under a low illuminance condition and, as a result, the photoelectric conversion efficiency was increased.

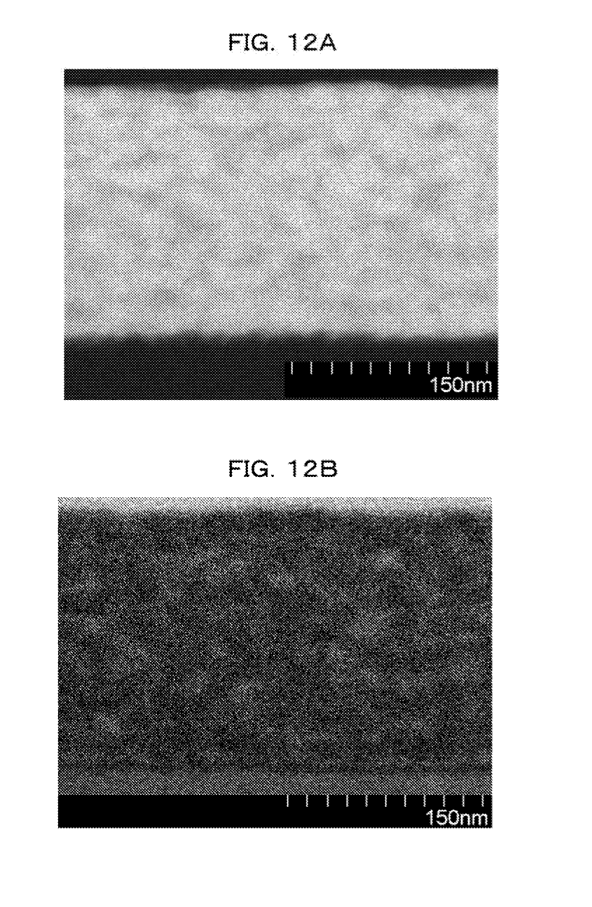

Here, FIGS. 12A and 12B depict mapping images of electron energy loss spectroscopy (EELS) performed taking, as a target, carbon nuclei and sulfur nuclei on a cross section of the sample of the example 2 (THF processing time period: 1 minute; THF liquid temperature: approximately 30° C.; device temperature: approximately 25° C.; thickness of photoelectric conversion layer: approximately 150 nm). Here, FIG. 12A depicts a mapping image taking carbon atoms as a target, namely, a mapping image (EELS-C; C-core) when plane analysis by the electron energy loss spectroscopy was performed and mapping of signals corresponding to carbon atoms was performed. Meanwhile, FIG. 12B depicts a mapping image taking sulfur atoms as a target, namely, a mapping image (EELS-C; S-core) when plane analysis by the electron energy loss spectroscopy was performed and mapping of signals corresponding to sulfur atoms was performed.

In the mapping image taking carbon atoms as a target depicted in FIG. 12A, a region in which the PC71BM in which the density of carbon atoms is high is a main constituent looks white. On the other hand, in the mapping image taking sulfur atoms as a target depicted in FIG. 12B, a region in which sulfur atoms contained only in the PCDTBT exist looks white. Then, it is recognized that the mapping image taking carbon atoms as a target depicted in FIG. 12A and the mapping image taking sulfur atoms as a target depicted in FIG. 12B are complementary to each other and the PC71BM as an n-type organic semiconductor material and the PCDTBT as a p-type organic semiconductor material are phase-separated in a size of approximately 10 to 30 nm. In particular, as depicted in FIGS. 12A and 12B, a pattern of contrast between light and shade is caused by advancement of the phase separation between the PC71BM as an n-type organic semiconductor material and the PCDTBT as a p-type organic semiconductor material. Further, the PC71BM forms substantially spherical shapes (substantially spherical aggregate structure) of a size of approximately 10 to 30 nm and the PCDTBT forms mesh shapes so as to fill up gaps of the PC71BM.

Further, in the mapping image (S-core image) taking sulfur atoms as a target depicted in FIG. 12B, a distribution state of sulfur atoms contained only in the PCDTBT from between the materials configuring the photoelectric conversion layer is indicated. Here, in FIG. 12B, the lower side is the positive electrode side and the upper side is the negative electrode side. In the S-core image depicted in FIG. 12B, signals (S-core signals) corresponding to sulfur atoms are poor in a region in the proximity of the interface with the negative electrode at the upper side (layered region; here, a region from the uppermost surface of the photoelectric conversion layer to the thickness (depth) of approximately 30 nm) in the photoelectric conversion layer. On the other hand, in the mapping image (C-core image) on which the concentration of the PC71BM is reflected strongly and which takes carbon atoms as a target depicted in FIG. 12A, a corresponding variation is not found. Therefore, the ratio of the PCDTBT is lowered in the region in the proximity of the interface with the negative electrode at the upper side (here, a region from the most surface of the photoelectric conversion layer 4 to the thickness (depth) of approximately 30 nm) in the photoelectric conversion layer. In particular, the photoelectric conversion layer includes a region in which the ratio of a p-type organic semiconductor material is lower than an average ratio at the negative electrode side.

Meanwhile, in the S-core image depicted in FIG. 12B, signals (S-core signals) corresponding to sulfur atoms are intensified in a region (layered region) in the proximity of the interface with a molybdenum oxide (VI) layer as the positive electrode side buffer layer at the lower side in the photoelectric conversion layer. Therefore, the ratio of the PCDTBT is raised in the region in the proximity of the interface with the molybdenum oxide (VI) layer as the positive electrode side buffer layer at the lower side in the photoelectric conversion layer. In particular, the photoelectric conversion layer includes a region in which the ratio of the p-type organic semiconductor material is higher than an average ratio at the positive electrode side.

Further, X-ray photoelectric spectrum (XPS) analysis was performed in the depthwise direction of the photoelectric conversion layer 4 in order to observe a composition distribution of the inside of the photoelectric conversion layer 4 of the sample of the example 1 described above (THF processing time period: 1 minute; THF liquid temperature: approximately 30° C.; device temperature: approximately 25° C.; thickness of photoelectric conversion layer: approximately 80 nm).

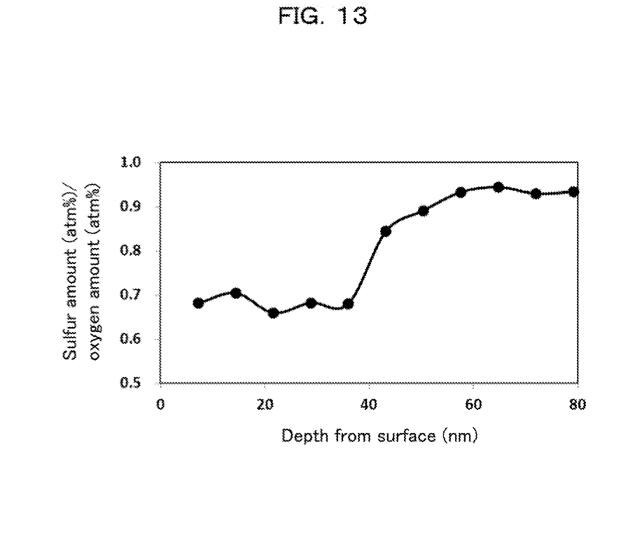

Here, from between the materials configuring the photoelectric conversion layer 4, only the PCDTBT as a p-type organic semiconductor material contains sulfur atoms and only the PC71BM as an n-type organic semiconductor material contains oxygen atoms. Therefore, oxygen atoms and sulfur atoms were determined as an observation target. Then, as a result of this, the ratio of sulfur atoms (atom %) to oxygen atoms (atom %) (profile in the depthwise direction) at each of different positions in the depthwise direction is depicted in FIG. 13. It is to be noted that the position of the depth of 0 nm is the most negative electrode side position of the photoelectric conversion layer 4, and the position of the depth of 80 nm is the most positive electrode side position of the photoelectric conversion layer 4. Further, data on the outermost surface are omitted since they are influenced much by surface contamination.

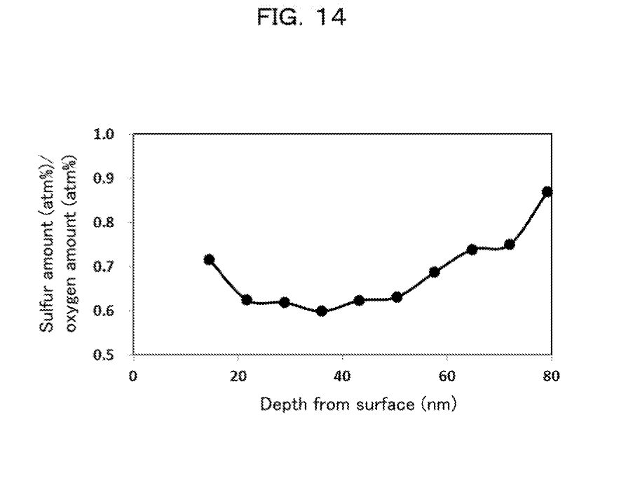

Further, for the comparison, a result when similar analysis was performed for the sample of the comparative example 1 described above for which the THF process was not performed is depicted in FIG. 14.

In the sample of the comparative example 1 described above for which the THF process was not performed, the molybdenum oxide (VI) layer as a positive electrode side buffer layer is formed. Therefore, the PCDTBT as a p-type organic semiconductor material is absorbed preferentially on the surface of the molybdenum oxide (VI) layer. As a result, as depicted in FIG. 14, in the sample of the comparative example 1 described above for which the THF process was not performed, the value of the ratio of the sulfur amount (atom %) to the oxygen amount (atom %) increases and the ratio of the PCDTBT increases toward the side of the positive electrode side buffer layer. In particular, the photoelectric conversion layer of the sample of the comparative example 1 exhibits a gentle inclination composition structure in which the ratio of the PCDTBT increases toward the positive electrode side buffer layer.

In contrast, in the sample of the example 1 described above, as depicted in FIG. 13, the thickness of a region in which the value of the rate of the sulfur amount (atom %) to the oxygen amount (atom %) at the positive electrode side buffer layer side is increased, namely, of a region in which the ratio of the PCDTBT at the positive electrode side buffer layer side is increased. Further, it is indicated that the region in which the ratio of the PDCTBT is relatively decreased is a region from the surface at the negative electrode side to the depth of approximately 35 nm. This similarly applies to the sectional structure depicted in FIG. 12B and suggests that the region just described ranges from the uppermost surface to the depth of approximately 30 nm under the conditions of the THF liquid temperature of approximately 30° C., device temperature of approximately 25° C. and vapor process time period of 1 minute, that are commonly applied to the samples of the example 1 and the comparative example 1.

In this manner, by further performing the THF process, for the product having such a composition distribution as in the sample of the comparative example 1 described above, as in the sample of the example 1 described above, the PCDTBT moves in a further deeper direction and the thickness of a region in which the value of the rate of the sulfur amount (atom %) to the oxygen amount (atom %) at the positive electrode side buffer layer side is increased, namely, of a region in which the ratio of the PCDTBT at the positive electrode side buffer layer side is increased, is increased. In this manner, it is recognized that a more preferable composition gradient structure in which a greater amount of PCDTBT is aggregated at the positive electrode side buffer layer side is obtained. The product having such a composition gradient structure as just described is preferable also in that the transportation efficiency of carries is improved.

It is to be noted that, in the sample of the example 1 described above, the liquid temperature of the THF and the vapor pressure of the THF are higher than those of the sample of an example 4 hereinafter described, and therefore, molecules of the THF are likely to adsorb to the surface of a mixture film and a greater amount of molecules of the THF advance into the inside of the mixture film. Therefore, the PCDTBT can be moved to a further deeper position and a greater amount of PCDTBTs are aggregated to the positive electrode side (or the positive electrode side buffer layer side), and, as a result, a more preferable composition gradient structure is obtained. The product having such a composition gradient structure as just described is preferable also in that the carrier transportation efficiency is improved.

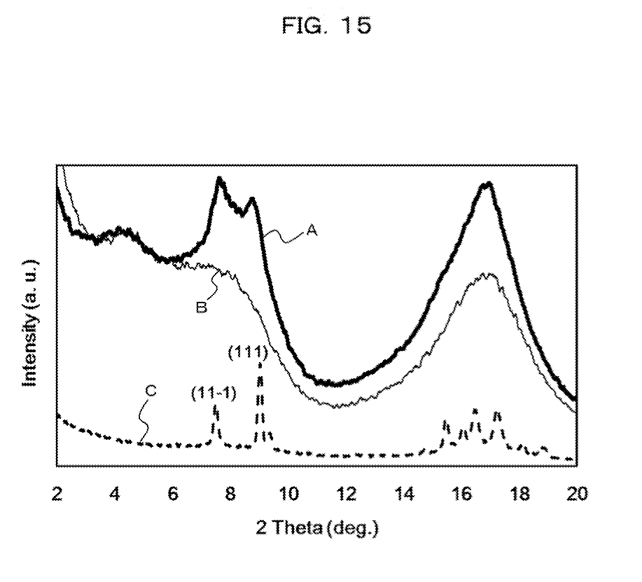

Further, FIG. 15 depicts an X-ray diffraction profile (XRD profile) obtained by performing an X-ray diffraction analysis for the sample of the example 1 (THF processing time: 1 minute; THF liquid temperature: approximately 30° C.; device temperature: approximately 25° C.; thickness of the photoelectric conversion layer: approximately 80 nm) and the sample of the comparative example 1 for which the THF process was not performed and then standardizing results of the X-ray diffraction analysis using the film thickness. It is to be noted that, in FIG. 15, a solid line A indicates the X-ray diffraction file of the photoelectric conversion layer provided in the sample of the example 1, and another solid line B indicates an X-ray diffraction profile of the photoelectric conversion layer provided in the sample of the example 1 for which the THF was not performed.

It is to be noted here that the X-ray diffraction profile is an X-ray diffraction profile obtained by scanning a detector in an in-plane direction of the sample (namely, in a direction parallel to the film surface) at a very small angle incidence position to measure a lattice plane perpendicular to the surface, and the wavelength of the X-ray is 1.54 angstrom and corresponds to CuKα. Further, since the film thickness of the photoelectric conversion layer of the samples has some dispersion, the X-ray diffraction profile is in a form standardized with the film thickness. In particular, the axis of ordinate in FIG. 15 indicates the standardized diffract ion strength. It is to be noted that, in FIG. 15, an X-ray diffraction profile of a single film (simple substance) of the PC71BM crystallized by performing annealing at approximately 150° C. is indicated by a broken line C.

First, as indicated by the solid line B in FIG. 15, the X-ray diffraction profile of the photoelectric conversion layer included in the comparative example 1 for which the THF process was not performed does not have a peak in the proximity of 2θ=7.5° and 9°. In contrast, as indicated by the solid line A in FIG. 15, the X-ray diffraction profile of the photoelectric conversion layer included in the sample of the example 1 described above has peaks in the proximity of 2θ=7.5° and 9°. In this manner, by performing the THF process, the peaks appear in the proximity of the 29=7.5° and 9° in the X-ray diffraction profile.

Here, as indicated by the broken line C in FIG. 15, the X-ray diffraction profile of the single film of the PC71BM crystalized by performing annealing at approximately 150° C. has peaks in the proximity of 2θ=7.5° and 9°. Further, the diffraction peak appearing in the proximity of 2θ=7.5° is a diffraction peak corresponding to (originating from) the (11-1) plane, and the diffraction peak appearing in the proximity of 2θ=9° is a diffraction peak corresponding to (originating from) the (111) plane.

In this manner, as indicated by the solid line A and the broken line C in FIG. 15, by performing the THF process, peaks corresponding to peaks existing in the proximity of the 28=7.5° and 9° appear in the X-ray diffraction profile of the single film of the PC71BM crystalized by performing annealing at approximately 150° C. In particular, the photoelectric conversion layer included in the sample of the example 1 described above has both diffraction peaks of a diffraction peak corresponding to the (111) plane and another diffraction peak corresponding to the (11-1) plane in the X-ray diffraction profile of the simple substance of the PC71BM. This indicates that, by performing the THF process, the PC71BM phase-separated in the photoelectric conversion layer is crystalized.

It is to be noted here that, while description is given taking, as an example, the case where the PCDTBT is used as a p-type organic semiconductor material and the PC71BM is used as an n-type organic semiconductor material, this similarly applies also to an alternative case wherein the p-type organic semiconductor material and the n-type organic semiconductor material used in the embodiment described above are used. In this manner, the photoelectric conversion layer has, in the X-ray diffraction profile thereof, both diffraction peaks of the diffraction peak corresponding to the (111) plane and the diffraction peak corresponding to the (11-1) plane in the X-ray diffraction profile of the simple substance of the n-type organic semiconductor material.

Also it is possible to improve the photoelectric conversion efficiency under a low illuminance condition from that of the sample of the example 2 described above. For example, by increasing the thickness of the photoelectric conversion layer, lowering the THF liquid temperature and increasing the THF processing time period similarly as in the case of the sample of the example 2 described above, the photoelectric conversion efficiency under a low illuminance condition can be further improved from that of the sample of the example 2 described above.

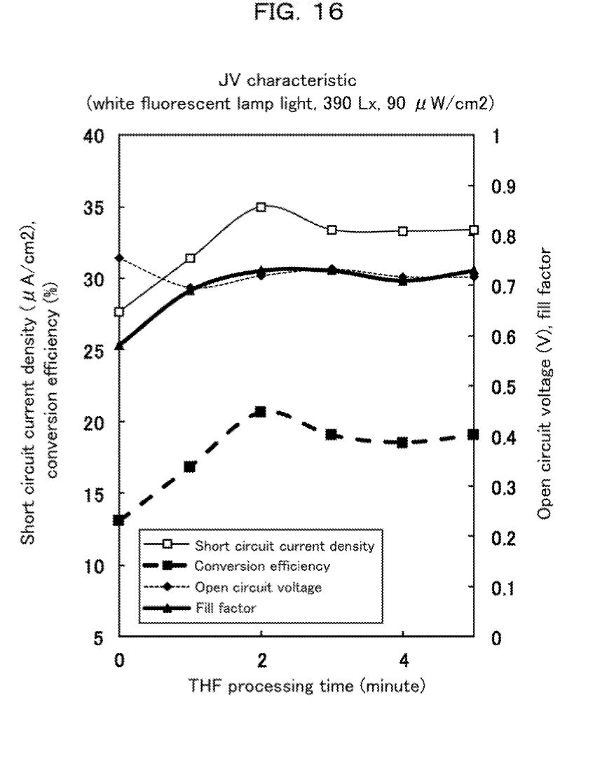

Here, FIG. 16 depicts a variation of a photoelectric conversion characteristic (JV characteristic; photoelectric conversion parameter) of the samples of the example 3 and comparative example 2 with respect to the THF processing time period under a white fluorescent lamp having an illuminance of 390 Lx and an irradiation illuminance 90 μW/cm².

As depicted in FIG. 16, under a white fluorescent lamp, namely, under a low illuminance condition, in the samples of the example 3 (THF processing time period: 1 to 5 minutes) in which the thickness of the photoelectric conversion layer, liquid temperature of the THF and device temperature were approximately 150 nm, approximately 25° C. and approximately 25° C., respectively, and for which the THF process was performed, the fill factor and the short circuit current density indicated maximum values where the THF processing time period was 2 minutes, and the fill factor and the short circuit current density were improved in comparison with those of the sample of the comparative example 2 in which the thickness of the photoelectric conversion layer was approximately 150 nm and for which the THF process was not performed (THF processing time period: 0 minute). As a result, under a low illuminance condition, the samples of the example 3 (THF processing time period: 1 to 5 minutes) in which the thickness of the photoelectric conversion layer was approximately 150 nm and for which the THF process was performed were improved in photoelectric conversion efficiency in comparison with the sample of the comparative example 2 (THF processing time period: 0 minute) in which the thickness of the photoelectric conversion layer was approximately 150 nm and for which the THF process was not performed. Particularly, the best photoelectric conversion efficiency was obtained by the THF processing time period of 2 minutes. In this manner, the samples of the example 3 (THF processing time period: 1 to 5 minutes) in which the thickness of the photoelectric conversion layer, liquid temperature of the THF and device temperature were approximately 150 nm, approximately 25° C. and approximately 25° C., respectively, and for which the THF process was performed were improved in photoelectric conversion efficiency under a low illuminance condition in comparison with the sample of the comparative example 2 in which the thickness of the photoelectric conversion layer was approximately 150 nm and for which the THF process was performed (THF processing time period: 0 minute), and, particularly, the best photoelectric conversion efficiency was obtained by the THF processing time period of 2 minutes.

Further, in the sample of the example 3 by which the best photoelectric conversion efficiency was obtained and with regard to which the THF processing time period was 2 minutes, the photoelectric conversion efficiency was approximately 21% under a low illuminance condition. In particular, under a low illuminance condition, in the sample of the example 3 in which the THF processing time period, THF liquid temperature, device temperature and thickness of photoelectric conversion layer were 2 minutes, approximately 25° C., approximately 25° C. and approximately 150 nm, respectively, the open circuit voltage (Voc), short circuit current density (Jsc), fill factor (FF), maximum power density (Pmax) and photoelectric conversion efficiency were approximately 0.719 V, approximately 35.0 μA/cm², approximately 0.73, approximately 18.3 μW/cm² and approximately 21%, respectively. In contrast, in the sample of the comparative example 2, the open circuit voltage (Voc), short circuit current density (Jsc), fill factor (FF), maximum power density (Pmax) and photoelectric conversion efficiency were approximately 0.754 V, approximately 27.7 μA/cm², approximately 0.58, approximately 12.1 μW/cm² and approximately 13%, respectively.

In this manner, under a low illuminance condition, the sample of the example 3 in which the THF processing time period, THF liquid temperature, device temperature and thickness of photoelectric conversion layer were 2 minutes, approximately 25° C., approximately 25° C. and approximately 150 nm, respectively, was improved in short circuit current density (Jsc) and fill factor (FF) in comparison with the sample of the comparative example 2, and, as a result, the photoelectric conversion efficiency was increased.

Further, under a low illuminance condition, the sample of the example 3 in which the THF processing time period, THF liquid temperature, device temperature and thickness of photoelectric conversion layer were 2 minutes, approximately 25° C., approximately 25° C. and approximately 150 nm, respectively, was improved in short circuit current density (Jsc) in comparison with the sample of the example 2 in which the THF processing time period, THF liquid temperature, device temperature and thickness of photoelectric conversion layer were 1 minute, approximately 30° C., approximately 25° C. and approximately 150 nm, respectively, and, as a result, the photoelectric conversion efficiency was increased.

It is to be noted that the samples of the example 3 (THF processing time period: 1 to 5 minutes) in which the thickness of the photoelectric conversion layer, liquid temperature of the THF and device temperature were approximately 150 nm, approximately 25° C. and approximately 25° C., respectively, and for which the THF process was performed were improved in short circuit current density (Jsc) and the fill factor (FF) also under a high illuminance condition in a solar simulator in comparison with the sample of the comparative example 2 for which the THF process was not performed, and, as a result, the photoelectric conversion efficiency was improved.

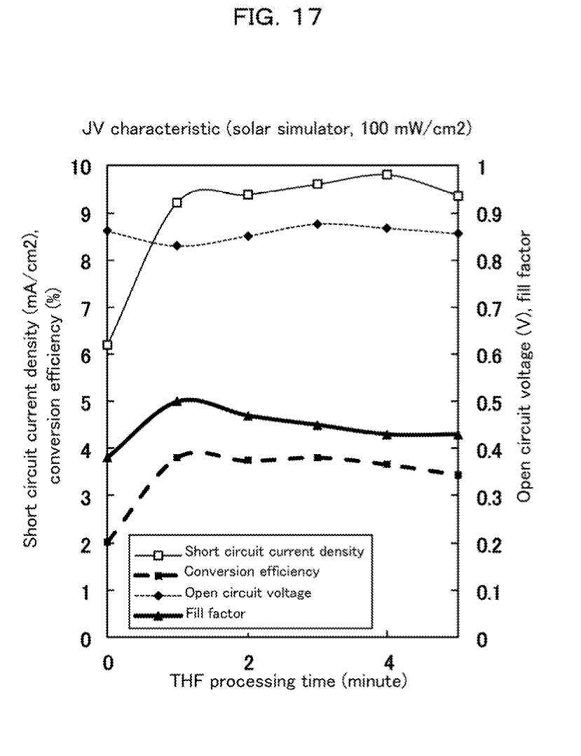

Here, FIG. 17 depicts variations of a photoelectric conversion characteristic (JV characteristic, photoelectric conversion parameter) of the samples of the example 3 and the comparative example 2 in a solar simulator wherein the AM (air mass) is 1.5 and the irradiation illuminance is 100 mW/cm² with respect to the THF processing time period of the samples.

As depicted in FIG. 17, in a high illumination condition of the solar simulator, the samples of the example 3 in which the thickness of the photoelectric conversion layer, liquid temperature of the THF and device temperature were approximately 150 nm, approximately 25° C. and approximately 25° C., respectively, and for which the THF process was performed (THF processing time period: 1 minute to 5 minutes) were improved in fill factor and short circuit current density in comparison with the sample of the comparative example 2 in which the thickness of the photoelectric conversion layer was approximately 150 nm and for which the THF process was not performed (THF processing time period: 0 minute). As a result, in a high illumination condition, the samples of the example 3 in which the thickness of the photoelectric conversion layer, liquid temperature of the THF and device temperature were approximately 150 nm, approximately 25° C. and approximately 25° C., respectively, and for which the THF process was performed (THF processing time period: 1 minute to 5 minutes) were improved in photoelectric conversion efficiency in comparison with the sample of the comparative example 2 in which the thickness of the photoelectric conversion layer was approximately 150 nm and for which the THF process was not performed (THF processing time period: 0 minute). In this manner, the samples of the example 3 in which the thickness of the photoelectric conversion layer, liquid temperature of the THF and device temperature were approximately 150 nm, approximately 25° C. and approximately 25° C., respectively, and for which the THF process was performed (THF processing time period: 1 minute to 5 minutes) were improved in photoelectric conversion efficiency also in high illumination condition in comparison with the sample of the comparative example 2 in which the thickness of the photoelectric conversion layer was approximately 150 nm and for which the THF process was not performed (THF processing time period: 0 minute).

Here, in a high illumination condition, the sample of the example 3 in which the THF processing time period was 2 minutes exhibited a photoelectric conversion efficiency of approximately 3.8%. In particular, in a high illumination condition, in the sample of the example 3 in which the THF processing time period, THF liquid temperature, device temperature and thickness of the optical conversion layer were 2 minutes, approximately 25° C., approximately 25° C. and approximately 150 nm, respectively, the open circuit voltage (Voc), short circuit current density (Jsc), fill factor (FF) and photoelectric conversion efficiency were approximately 0.851 V, approximately 9.38 μA/cm², approximately 0.47 and approximately 3.8%, respectively. Meanwhile, in the sample of the comparative example 2, the open circuit voltage (Voc), short circuit current density (Jsc), fill factor (FF) and photoelectric conversion efficiency were approximately 0.861 V, approximately 6.19 μA/cm², approximately 0.38 and approximately 2.0%, respectively. In this manner, the samples of the example 3 were improved in short circuit current density (Jsc) and fill factor (FF), and as a result, the photoelectric conversion efficiency was improved.

By performing the THF process at the THF liquid temperature of 25° C. and the device temperature of approximately 25° C. for 2 minutes, even if the thickness of the photoelectric conversion layer was great, the short circuit current density (Jsc) and the fill factor (FF) were improved in both conditions of a high illuminance condition and a low illuminance condition. As a result, the photoelectric conversion efficiency was improved.

It is to be noted that, although the sample of the example 3 here is a sample in which the THF processing time period, THF liquid temperature, device temperature and thickness of the optical conversion layer were 2 minutes, approximately 25° C., approximately 25° C. and approximately 150 nm, respectively, a similar effect was obtained also where the THF processing time was 3 minutes.

Also mapping images by electron energy loss spectroscopy, performed for carbon nuclei and sulfur nuclei as a target, of a cross section of the sample of the example 3 (THF processing time: 3 minutes; THF liquid temperature: approximately 25° C.; device temperature: approximately 25° C.; thickness of the photoelectric conversion layer: approximately 150 nm) were similar to mapping images by electron energy loss spectroscopy, performed for carbon nuclei and sulfur nuclei as a target, of a cross section of the sample of the example 2 described hereinabove.

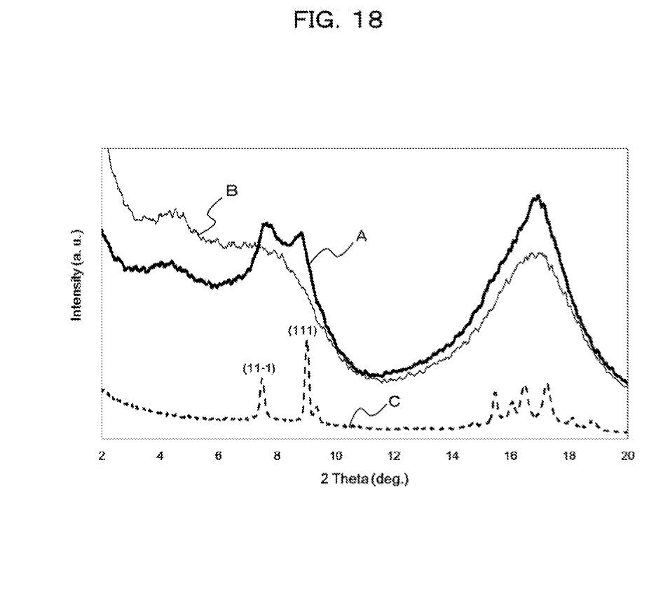

Meanwhile, FIG. 18 depicts an X-ray diffraction profile (XRD profile) obtained by performing an X-ray diffraction analysis of the sample of the example 3 (THF processing time: 3 minute; THF liquid temperature: approximately 25° C.; device temperature: approximately 25° C.; thickness of the photoelectric conversion layer: approximately 150 nm) and the sample of the comparative example 2 for which the THF process was not performed and then standardizing results of the X-ray diffraction analysis using the film thickness. It is to be noted that, in FIG. 18, a solid line A indicates the X-ray diffraction file of the photoelectric conversion layer provided in the sample of the example 3, and another solid line B indicates an X-ray diffraction profile of the photoelectric conversion layer provided in the sample of the comparative example 2 for which the THF was not performed.

It is to be noted here that the X-ray diffraction profile is an X-ray diffraction profile obtained by scanning a detector in an in-plane direction of the sample (namely, in a direction parallel to the film surface) at a very small angle incidence position to measure a lattice plane perpendicular to the surface, and the wavelength of the X-ray is 1.54 angstrom and corresponds to CuKα. Further, since the film thickness of the photoelectric conversion layer of the samples has some dispersion, the X-ray diffraction profile is depicted in a form standardized with the film thickness. In particular, the axis of ordinate in FIG. 18 indicates the standardized diffraction strength. It is to be noted that, in FIG. 18, an X-ray diffraction profile of a single film (simple substance) of the PC71BM crystallized by performing annealing at approximately 150° C. is indicated by a broken line C.

First, as indicated by the solid line B in FIG. 18, the X-ray diffraction profile of the photoelectric conversion layer provided in the sample of the comparative example 2 for which the THF process was not performed does not have peaks in the proximity of 2θ=7.5° and 9°. In contrast, as indicated by the solid line A in FIG. 18, the X-ray diffraction profile of the photoelectric conversion layer provided in the sample of the comparative example 3 described hereinabove has peaks in the proximity of each of 2θ=7.5° and 9°. In this manner, peaks appear in the proximity of 2θ=7.5° and 9° in the X-ray diffraction profile by performing the THF process.

Here, as indicated by the broken line C in FIG. 18, the X-ray diffraction profile of a single film of the PC71BM crystallized by performing annealing at approximately 150° C. has a peak in the proximity of each of 2θ=7.5° and 9°. The diffraction peak appearing in the proximity of 2θ=7.5° is a diffraction peak corresponding to (originating from) the (11-1) plane, and the diffraction peak appearing in the proximity of 28=9° is a diffraction peak corresponding to (originating from) the (111) plane.

In this manner, as indicated by the solid line A and the broken line C in FIG. 18, by performing the THF process, peaks corresponding to the peaks existing in the proximity of 2θ=7.5° and 9° appear on the X-fay diffraction profile of a single film of the PC71BM crystallized by performing annealing at approximately 150° C. In short, the photoelectric conversion layer provided in the sample of the example 3 described above has, on the X-ray diffraction profile thereof, diffraction peaks of both of a diffraction peak corresponding to the (111) plane and a diffraction peak corresponding to the (11-1) plane in the X-ray diffraction profile of a simple substance of the PC71BM. This indicates that, by performing the THF process, the PC71BM phase-separated in the photoelectric conversion layer is crystallized.

Then, also a sample of an example 4 that includes a photoelectric conversion element having a thickness of approximately 80 nm by changing the thickness of the photoelectric conversion layer of the sample of the example 3 and in which the liquid temperature of the THF, device temperature and THF processing time period were approximately 25° C., approximately 25° C. and 2 minutes, respectively, was improved in short circuit current density (Jsc) and fill factor (FF) under both of a high illuminance condition and a low illuminance condition in comparison with the sample of the comparative example 1 in which the thickness of the photoelectric conversion layer was approximately 80 nm and for which the THF process was not performed. As a result, the photoelectric conversion efficiency was improved under a high illuminance condition, and an equivalent photoelectric conversion efficiency was obtained under a low illuminance condition. However, the samples of the examples 1 to 3 described hereinabove were improved in short circuit current density (Jsc) and fill factor (FF) under both of a high illuminance condition and a low illuminance condition. As a result, the photoelectric conversion efficiency was improved.

In particular, under a high illuminance condition by a solar simulator (AM (air mass): 1.5, irradiation illuminance 100 mW/cm²), in the sample of the example 4 in which the THF processing time period, THF liquid temperature, device temperature and thickness of the photoelectric conversion layer were 2 minutes, approximately 25° C., approximately 25° C. and approximately 80 nm, respectively, the open circuit voltage (Voc), short circuit current density (Jsc), fill factor (FF) and photoelectric conversion efficiency were approximately 0.832 V, approximately 7.90 μA/cm², approximately 0.56 and approximately 3.7%, respectively. Meanwhile, in the sample of the comparative example 1, the open circuit voltage (Voc), short circuit current density (Jsc), fill factor (FF) and photoelectric conversion efficiency were approximately 0.893 V, approximately 7.03 mA/cm², approximately 0.44 and approximately 2.8%, respectively. In this manner, under a high illuminance condition, the sample of the example 4 was improved in short circuit current density (Jsc) and fill factor (FF) in comparison with the sample of the comparative example 1. As a result, the photoelectric conversion efficiency was improved.

Meanwhile, under a white fluorescent lamp of an illuminance of 390 Lx and an irradiation illuminance of 90 μW/cm², namely, under a low illuminance condition, in the sample of the example 4 in which the THF processing time period, THF liquid temperature, device temperature and thickness of the photoelectric conversion layer were 2 minutes, approximately 25° C., approximately 25° C. and approximately 80 nm, respectively, the open circuit voltage (Voc), short circuit current density (Jsc), fill factor (FF), maximum power density (Pmax) and photoelectric conversion efficiency were approximately 0.688 V, approximately 26.9 μA/cm², approximately 0.70, approximately 12.9 μW/cm² and approximately 14%, respectively. Meanwhile, in the sample of the comparative example 1, the open circuit voltage (Voc), short circuit current density (Jsc), fill factor (FF), maximum power density (Pmax) and photoelectric conversion efficiency were approximately 0.760 V, approximately 25.8 μA/cm², approximately 0.64, approximately 12.6 ti/cm² and approximately 14%, respectively. In this manner, under a low illuminance condition, the sample of the example 4 was improved in short circuit current density (Jsc) and fill factor (FF) in comparison with the sample of the comparative example 1. Further, an equivalent photoelectric conversion efficiency was obtained.

By performing the THF process at the THF liquid temperature of 25° C. and the device temperature of approximately 25° C. for 2 minutes in this manner, even if the thickness of the photoelectric conversion layer was small, the short circuit current density (Jsc) and the fill factor (FF) were improved in both conditions of a high illuminance condition and a low illuminance condition. As a result, the photoelectric conversion efficiency was improved under a high illuminance condition, and an equivalent photoelectric conversion efficiency was obtained under a low illuminance condition.

It is to be noted that, although the sample of the example 4 here is a sample in which the THF processing time period, THF liquid temperature, device temperature and thickness of the optical conversion layer were 2 minutes, approximately 25° C., approximately 25° C. and approximately 80 nm, respectively, a similar effect was obtained also where the THF processing time was 3 minutes.

Then, also in a sample of an example 5 in which the THF processing time, THF liquid temperature, device temperature and thickness of the photoelectric conversion layer were 2 minutes, approximately 40° C., approximately 40° C. and approximately 80 nm, respectively, the photoelectric conversion efficiency under a high illuminance was improved and an equal photoelectric conversion efficiency was obtained in comparison with the example of the comparative example 1 in which the thickness of the photoelectric conversion layer was approximately 80 nm and for which the THF process was not performed.

In particular, under a high illuminance condition by a solar simulator (AM (air mass): 1.5, irradiation illuminance: 100 mW/cm²), in the sample of the example 5 in which the THF processing time period, THF liquid temperature, device temperature and thickness of the photoelectric conversion layer were 2 minutes, approximately 40° C., approximately 40° C. and approximately 80 nm, respectively, the open circuit voltage (Voc), short circuit current density (Jsc), fill factor (FF) and photoelectric conversion efficiency were approximately 0.895 V, approximately 7.58 μA/cm², approximately 0.5 and approximately 3.4%, respectively. Meanwhile, in the sample of the comparative example 1, the open circuit voltage (Voc), short circuit current density (Jsc), fill factor (FF) and photoelectric conversion efficiency were approximately 0.893 V, approximately 7.03 mA/cm², approximately 0.44 and approximately 2.8%, respectively. In this manner, under a high illuminance condition, the sample of the example 5 was improved in short circuit current density (Jsc) and fill factor (FF) in comparison with the sample of the comparative example 1. As a result, the photoelectric conversion efficiency was improved.

Meanwhile, under a white fluorescent lamp of the illuminance of 390 Lx and the irradiation illuminance of 90 μW/cm², namely, under a low illuminance condition, in the sample of the example 5 in which the THF processing time period, THF liquid temperature, device temperature and thickness of the photoelectric conversion layer were 2 minutes, approximately 40° C., approximately 40° C. and approximately 80 nm, respectively, the open circuit voltage (Voc), short circuit current density (Jsc), fill factor (FF), maximum power density (Pmax) and photoelectric conversion efficiency were approximately 0.757 V, approximately 26.2 μA/cm², approximately 0.63, approximately 12.8 μW/cm² and approximately 14%, respectively. Meanwhile, in the comparative example 1, the open circuit voltage (Voc), short circuit current density (Jsc), fill factor (FF), maximum power density (Pmax) and photoelectric conversion efficiency were approximately 0.760 V, approximately 25.8 μA/cm², approximately 0.64, approximately 12.6 μW/cm² and approximately 14%, respectively. In this manner, under a low illuminance condition, the sample of the example 5 was improved in short circuit current density (Jsc) in comparison with the sample of the comparative example 1, and an equivalent photoelectric conversion efficiency was obtained. It is to be noted that, under a low illuminance condition, the fill factor (FF) was not improved.

By performing the THF process at the THF liquid temperature of 40° C. and the device temperature of approximately 40° C. for 2 minutes in this manner, even if the thickness of the photoelectric conversion layer was small, the photoelectric conversion efficiency was improved under a high illuminance condition, and an equivalent photoelectric conversion efficiency was obtained under a low illuminance condition in comparison with the sample of the comparative example 1 in which the thickness of the photoelectric conversion layer was approximately 80 nm and for which the THF process was not performed.

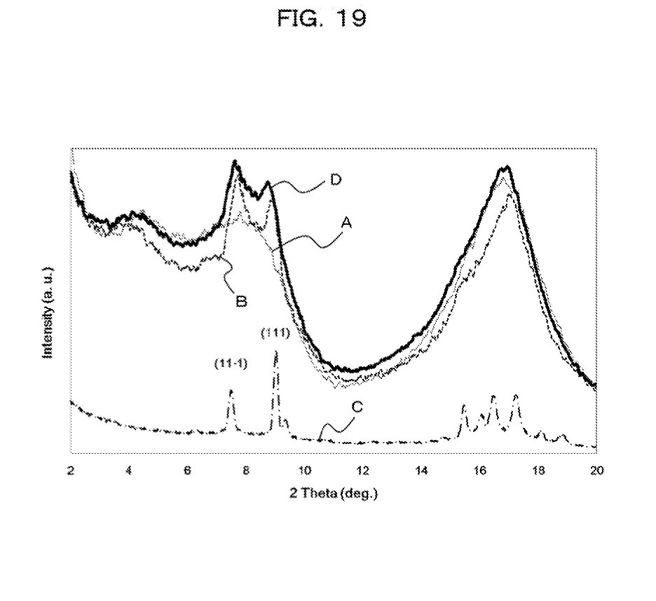

In the sample of the example 5, as indicated by a solid line A in FIG. 19, the photoelectric conversion layer has, in an X-ray diffraction profile thereof, a diffraction peak corresponding to the (11-1) plane of the X-ray diffraction profile of the simple substance of the PC71BM, but does not have a diffraction peak corresponding to the (111) plane. Therefore, it is considered that, in the sample of the example 5, although the PC71BM in the photoelectric conversion layer comes close to a crystal state, the crystallization does not advance so much as in the examples described hereinabove or in an example hereinafter described. As a result, it is considered that the fill factor (FF) was not improved under a low illuminance condition. In other words, it is considered that the fill factor (FF) is improved if the crystallization advances to such a degree that the X-ray diffraction profile has both diffraction peaks including a diffraction peak corresponding to the (111) plane and a diffraction peak corresponding to the (11-1) plane of the x-ray diffraction profile of the simple substance of the PC71BM. However, if the photoelectric conversion layer is crystallized to such a degree that the X-ray diffraction profile thereof has a diffraction peak corresponding to the (111) plane of the X-ray diffraction profile of the simple substance of the PC71BM as in the example 5, then the photoelectric conversion efficiency is improved under a high illuminance condition and an equivalent photoelectric conversion efficiency is obtained under a low illuminance condition in comparison with that in an alternative case in which the THF process is not performed. It is to be noted that, in FIG. 19, an X-ray diffraction profile of the single film (simple substance) of the PC71BM crystallized by performing annealing at approximately 150° C. is indicated by a dot-and-dash line C. Further, in FIG. 19, an X-ray diffraction profile of the sample of the example 1 described hereinabove (THF processing time period: 1 minute; THF liquid temperature: approximately 30° C.; device temperature: 25° C.; thickness of the photoelectric conversion layer: approximately 80 nm) is indicated by a thick solid line D.

It is to be noted that it is considered that, similarly to the fact that, in comparison with the sample of the example 4 described hereinabove, the sample of the example 3 is improved, because the film thickness of the photoelectric conversion layer 4 is increased, in short circuit current density (Jsc) and fill factor (FF) under both conditions of a high illuminance condition and a low illuminance condition and, as a result, the photoelectric conversion efficiency is improved, if the film thickness of the photoelectric conversion layer is increased in comparison with the sample of the example 5, then the short circuit current density (Jsc) and the fill factor (FF) are improved under both of a high illuminance condition and a low illuminance condition, and as a result, the photoelectric conversion efficiency is improved.

Further, where the liquid temperature of the THF and the device temperature are equal as in the sample of the example 5 or the samples of the examples 3 and 4, molecules of the THF are less likely to adsorb to the surface of the mixture film and the number of molecules of the THF which enter the inside of the mixture film is reduced. This is because, since the temperature of vapor of the THF emitted from a vapor source becomes lower than the liquid temperature of the THF that is the vapor source, the device temperature, namely, the temperature of the surface of the photoelectric conversion layer 4, becomes higher. In contrast, by making the liquid temperature of the THF higher than the device temperature (namely, by making the temperature of the solvent as the vapor source where a vapor process is performed higher than the temperature of the mixture film), as in the examples 1 and 2 described hereinabove or an example hereinafter described, it is possible to allow molecules of the THF to likely adsorb on to the surface of the mixture film and increase molecules of the THF which advance into the inside of the mixture film. The photoelectric conversion efficiency can be further improved thereby.

In addition, also it is possible to further improve the fill factor (FF) of the sample of the example 1 described hereinabove (THF liquid temperature: approximately 30° C.; THF process time period: 1 minute; device temperature: approximately 25° C.; thickness of the photoelectric conversion layer: approximately 80 nm). For example, by setting the THF liquid temperature, THF processing time period, device temperature and thickness of the photoelectric conversion layer to approximately 40° C., 2 minutes, approximately 25° C. and approximately 80 nm, respectively, the fill facture (FF) can be improved with respect to the sample of the example 1 described hereinabove. By raising the liquid temperature of the THF in this manner, it is possible to further improve the fill factor (FF). Here, if the liquid temperature of the THF is raised, then since the vapor pressure of the THF becomes high, molecules of the THF become liable to adsorb to the surface of the mixture film, and a greater amount of molecules of the THF advance into the inside of the mixture film. Therefore, phase separation of the PCDTBT and the PC71BM further progresses, and although the size of the PC71BM of a substantially spherical shape becomes greater, crystallization will proceed further. Also in this case, similarly to the sample of the example 1 described hereinabove, the photoelectric conversion layer has, on an X-ray diffraction profile, both diffraction peaks including a diffraction peak corresponding to the (111) plane and another diffraction peak corresponding to the (11-1) plane of the X-ray diffraction profile of the simple substance of the PC71BM as indicated by a broken line B in FIG. 19. Further, since movement to the PCDTBT at a deeper position is performed, a region in which the ratio of the PCDTBT formed at the surface side (namely, at the negative electrode side) is lower than an average ratio, namely, a region formed at the surface side and including the PC71BM as a main constituent, becomes thick, and the recombination probability of carriers drops. As a result, the fill factor (FF) is further improved.

All examples and conditional language provided herein are intended for the pedagogical purposes of aiding the reader in understanding the invention and the concepts contributed by the inventor to further the art, and are not to be construed as limitations to such specifically recited examples and conditions, nor does the organization of such examples in the specification relate to a showing of the superiority and inferiority of the invention. Although one or more embodiments of the present invention have been described in detail, it should be understood that the various changes, substitutions, and alterations could be made hereto without departing from the spirit and scope of the invention.

What is claimed is:

1. A fabrication method for a photoelectric conversion device, comprising:
forming a photoelectric conversion layer; wherein
the forming a photoelectric conversion layer includes:
applying and drying mixed liquid including poly-[N-9′-heptadecanyl-2,7-carbazole-alt-5,5-(4′,7′-di-2-thienyl2′,1′,3′-benzothiadiazle)] as a p-type organic semiconductor material and a fullerene derivative as an n-type organic semiconductor material, which configure a bulk heterojunction; and
exposing the dried substance in an atmosphere including vapor of a solvent that dissolves the p-type organic semiconductor material preferentially to the n-type organic semiconductor material.

2. The fabrication method for a photoelectric conversion device according to claim 1, wherein tetrahydrofuran is used as the solvent.

3. The fabrication method for a photoelectric conversion device according to claim 1, wherein the fullerene derivative contains any one material selected from the group consisting of [6,6]-phenyl-C₇₁-butyric acid methyl ester, [6,6]-phenyl-C₆₁-butyric acid methyl ester and [6,6]-phenyl-C₈₅-butyric acid methyl ester.

4. The fabrication method for a photoelectric conversion device according to claim 1, wherein, in the forming a photoelectric conversion layer, the n-type organic semiconductor material is at least partially crystallized by exposing the dried substance in the atmosphere including vapor of the solvent.

5. The fabrication method for a photoelectric conversion device according to claim 1, wherein, in the forming a photoelectric conversion layer, a photoelectric conversion layer having both of a diffraction peak corresponding to a (111) plane and another diffraction peak corresponding to a (11-1) plane in an X-ray diffraction profile of a simple substance of the n-type organic semiconductor material in an X-ray diffraction profile is formed by exposing the dried substance in the atmosphere including vapor of the solvent.

6. The fabrication method for a photoelectric conversion device according to claim 1, wherein, in the forming a photoelectric conversion layer, a photoelectric conversion layer including a region in which a ratio of the p-type organic semiconductor material is lower than an average ratio is formed at the surface side by exposing the dried substance in the atmosphere including vapor of the solvent; and
the fabrication method further comprises forming a negative electrode over the surface of the photoelectric conversion layer after the forming a photoelectric conversion layer.

7. The fabrication method for a photoelectric conversion device according to claim 1, further comprising forming a positive electrode and forming a positive electrode side buffer layer before the forming a photoelectric conversion layer; wherein
in the forming a photoelectric conversion layer, a photoelectric conversion layer including a region in which a ratio of the p-type organic semiconductor material is higher than an average ratio at the side of the positive electrode side buffer layer and another region in which the ratio of the p-type organic semiconductor material is lower than the average ratio at the opposite side to the positive electrode side buffer layer is formed on the positive electrode side buffer layer.

8. A photoelectric conversion device, comprising:
a positive electrode;
a negative electrode; and
a photoelectric conversion layer that is provided between the positive electrode and the negative electrode, includes a p-type organic semiconductor material and an n-type organic semiconductor material, which configure a bulk heterojunction, includes poly-[N-9′-heptadecanyl-2,7-carbazole-alt-5,5-(4′,7′-di-2-thienyl2′,1′,3′-benzothiadiazle)] as the p-type organic semiconductor material, and includes a fullerene derivative as the n-type organic semiconductor material and in which the n-type organic semiconductor material at least partially forms crystal.

9. The photoelectric conversion device according to claim 8, wherein the fullerene derivative includes any one material selected from the group consisting of [6,6]-phenyl-C₇₁-butyric acid methyl ester, [6,6]-phenyl-C₆₁-butyric acid methyl ester and [6,6]-phenyl-C₈₅-butyric acid methyl ester.

10. The photoelectric conversion device according to claim 8, wherein the photoelectric conversion layer has, in an X-ray diffraction profile, both of a diffraction peak corresponding to a (111) plane and another diffraction peak corresponding to a (11-1) plane in an X-ray diffraction profile of a simple substance of the n-type organic semiconductor material.

11. The photoelectric conversion device according to claim 8, wherein the photoelectric conversion layer includes a region in which a ratio of the p-type organic semiconductor material is lower than an average ratio at the surface side; and
the negative electrode is provided over the surface of the photoelectric conversion layer.

12. The photoelectric conversion device according to claim 8, further comprising a positive electrode side buffer layer provided between the photoelectric conversion layer and the positive electrode; wherein
the photoelectric conversion layer includes a region in which a ratio of the p-type organic semiconductor material is higher than an average ratio at the side of the positive electrode side buffer layer and another region in which the ratio of the p-type organic semiconductor material is lower than the average ratio at the side of the negative electrode.

13. The photoelectric conversion device according to claim 12, wherein the positive electrode side buffer layer includes a material in which energy of the lowest unoccupied electron orbit is shallower than that of the n-type organic semiconductor material and energy of the highest unoccupied electron orbit is shallower than that of the p-type organic semiconductor material.

14. The photoelectric conversion device according to claim 8, further comprising a negative electrode side buffer layer provided between the photoelectric conversion layer and the negative electrode and including a material in which energy of the highest unoccupied electron orbit is deeper than that of the p-type organic semiconductor material and energy of the lowest unoccupied electron orbit is deeper than that of the n-type organic semiconductor material.

15. The photoelectric conversion device according to claim 8, further comprising a hole blocking layer provided between the photoelectric conversion layer and the negative electrode and including lithium fluoride or metallic calcium.
